(19) United States
(12) Patent Application Publication
(10) Pub. No.: US 2024/0206164 A1
(43) Pub. Date: Jun. 20, 2024

(54) THREE-DIMENSIONAL MEMORY DEVICES AND SYSTEM HAVING THE SAME

(71) Applicant: YANGTZE MEMORY TECHNOLOGIES CO., LTD., Wuhan (CN)

(72) Inventors: Zongliang Huo, Wuhan (CN); Wenbin Zhou, Wuhan (CN); Lei Zhang, Wuhan (CN); Han Yang, Wuhan (CN)

(21) Appl. No.: 18/090,885

(22) Filed: Dec. 29, 2022

(30) Foreign Application Priority Data
Dec. 14, 2022 (CN) 202211608340.3

(51) Int. Cl. H10B 43/27; H01L 23/535; H10B 41/27

(52) U.S. Cl. CPC H01L 27/11582; H01L 23/535; H01L 27/11556

(57) ABSTRACT

In certain aspects, a three-dimensional (3D) memory device includes a semiconductor layer; a stack structure on the semiconductor layer, one or more stop structures, and second dielectric layers. The stack structure includes alternating conductive layers and first dielectric layers and has a core region and a staircase region adjacent to the core region. The one or more stop structures are in contact with the corresponding conductive layers and extend through the staircase region of the stack structure in a first direction toward the semiconductor layer. Each of the second dielectric layers is between two of the first dielectric layers. Each of the one or more stop structures is between one of the second dielectric layers and one of the conductive layers.

### CROSS-REFERENCE TO RELATED APPLICATIONS

This application claims the benefit of priority to Chinese Application No. 202211608340.3, filed Dec. 14, 2022, which is incorporated herein by reference in its entirety.

### BACKGROUND

The present disclosure relates to memory devices, and systems having the same.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation of planar memory cells. The 3D memory architecture includes a memory array and peripheral circuits for facilitating operations of the memory array.

### SUMMARY

In one aspect, a three-dimensional (3D) memory device includes a semiconductor layer; a stack structure on the semiconductor layer, one or more stop structures, and second dielectric layers. The stack structure includes alternating conductive layers and first dielectric layers and has a core region and a staircase region adjacent to the core region. The one or more stop structures are in contact with the corresponding conductive layers and extend through the staircase region of the stack structure in a first direction toward the semiconductor layer. Each of the second dielectric layers is between two of the first dielectric layers. Each of the one or more stop structures is between one of the second dielectric layers and one of the conductive layers.

In some implementations, a material of the second dielectric layers is different from that of the stop structures.

In some implementations, a material of the second dielectric layers and that of the stop structures have an etching selectivity of equal or more than 5.

In some implementations, one or more first stop structures of the stop structures extends in a second direction perpendicular to the first direction and one or more second stop structure of the stop structures extends in a third direction perpendicular to the first direction and the second direction.

In some implementations, one of the first stop structures connects between two of the second stop structures.

In some implementations, the 3D memory device further includes one or more first supporting structures in contact with the semiconductor layer and extending through the core region of the stack structure, and one or more second supporting structures in contact with the semiconductor layer and extending through the staircase region of the stack structure.

In some implementations, a diameter of each of the second supporting structures is larger than a width of each of the stop structures.

In some implementations, a diameter of each of the second supporting structures is ranged from 50 nm to 300 nm.

In some implementations, a material of the one or more second supporting structure comprises silicon oxide, silicon nitride, silicon oxynitride, aluminum oxide, or a combination thereof.

In some implementations, the second supporting structures are arranged side-by-side along a second direction in which stop structures extending, wherein the second direction is perpendicular to the first direction.

In some implementations, each of the second supporting structures is in contact with one of the stop structures.

In some implementations, each of the second supporting structures is not in contact with one of the stop structures.

In some implementations, one or more first stop structures of the stop structures extends in a second direction perpendicular to the first direction, and one or more second stop structure of the stop structures extends in a third direction perpendicular to the first direction and the second direction, one of the first stop structures connects between two of the second stop structures, and one of the second stop structures extends in the first direction and is in contact with one of the first dielectric layer.

In some implementations, one of the second stop structures has a rectangular cross-section.

In some implementations, one or more first stop structures of the stop structures extends in a second direction perpendicular to the first direction, and one or more second stop structure of the stop structures extends in a third direction perpendicular to the first direction and the second direction, one of the first stop structures connects between two of the second stop structures, and one of the second stop structures has a stepwise cross-section.

In another aspect, a system includes a three-dimensional (3D) memory device configured to store data, and a memory controller coupled to the 3D memory device and configured to control the 3D memory device. The 3D memory device includes a semiconductor layer, a stack structure on the semiconductor layer, one or more stop structures, and second dielectric layers. The stack structure includes alternating conductive layers and first dielectric layers and has a core region and a staircase region adjacent to the core region. The one or more stop structures is in contact with the corresponding conductive layers and extends through the staircase region of the stack structure in a first direction toward the semiconductor layer. Each of the second dielectric layers is between two of the first dielectric layers. Each of the one or more stop structures is between one of the second dielectric layers and one of the conductive layers.

In still another aspect, a method for a three-dimensional (3D) memory device includes forming a stack structure on a semiconductor layer, wherein the stack structure comprises alternating sacrificial layers and dielectric layers and has a core region and a staircase region adjacent to the core region, forming one or more stop structures in contact with the corresponding dielectric layers and extending through the staircase region of the stack structure in the first direction toward the semiconductor layer, and replacing a part of the sacrificial layers with conductive layers. Each of the one or more stop structures is between one of the sacrificial layers and one of the conductive layers.

In some implementations, the method further includes forming one or more contact structures in contact with the corresponding conductive layers.

In some implementations, replacing a part of the sacrificial layers with conductive layers includes etching to remove the part of the sacrificial layers until the one or more stop structures, and filling vacancies after removing the part of the sacrificial layers with conductive materials.

In some implementations, the method further includes forming one or more first supporting structures in contact with the semiconductor layer and extending through the core region of the stack structure in the first direction toward the semiconductor layer, and forming one or more second supporting structures in contact with the semiconductor layer and extending through the staircase region of the stack structure. Each of the second supporting structures is in contact with one of the stop structures.

In some implementations, forming one or more second supporting structures in contact with the semiconductor layer and extending through the staircase region of the stack structure further includes etching of the stack structure to form one or more second supporting structure through holes overlapping at least a part of the one or more stop structures, and filling the one or more second supporting structure through holes with dielectric materials to form the one or more second supporting structures.

In some implementations, forming one or more first supporting structures in contact with the semiconductor layer and extending through the core region of the stack structure in the first direction toward the semiconductor layer further includes etching of the stack structure to form one or more first supporting structure through holes in the core region of the stack structure extending to the semiconductor layer in the first direction, and filling the one or more first supporting structure through holes with dielectric materials to form the one or more first supporting structures.

In some implementations, forming one or more stop structures in contact with the corresponding dielectric layers and extending through the staircase region of the stack structure in the first direction further includes forming a hard mask on the stack structure with a pattern, etching through a first pair of the sacrificial layers and dielectric layers of the stack structure via a first part of the pattern of the hard mask by covering up the rest part of the pattern with a photoresist layer on the hard mask, trimming the photoresist layer to uncover a second part of the pattern of the hard mask, and etching through a second pair of the sacrificial layers and dielectric layers of the stack structure via the first part of the pattern of the hard mask, and etching through the first pair of the sacrificial layers and dielectric layers of the stack structure via the second part of the pattern of the hard mask.

In some implementations, etching through a first pair of the sacrificial layers and dielectric layers of the stack structure includes etching through the stack structure until a pre-determined condition is met. The pre-determined condition comprises detecting a pre-determined element of etching residues.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic circuit diagram of an exemplary 3D memory device including peripheral circuits, according to some implementations of the present disclosure.

FIG. 2 illustrates a block diagram of an exemplary 3D memory device including a memory cell array and peripheral circuits, according to some implementations of the present disclosure.

FIG. 3 illustrates a cross-sectional view of an exemplary 3D memory device, according to some implementations of the present disclosure.

FIG. 4A illustrates a plan view of an exemplary 3D memory device, according to some implementations of the present disclosure.

FIGS. 4B and 4C illustrate cross-sectional views of a 3D memory device, according to some implementations of the present disclosure.

FIGS. 5A-5O illustrate a fabrication process for forming an exemplary 3D memory device, according to various embodiments of the present disclosure.

FIGS. 6A-6N illustrate a fabrication process for forming an exemplary 3D memory device, according to various embodiments of the present disclosure.

FIGS. 7A-7N illustrate a fabrication process for forming an exemplary 3D memory device, according to various embodiments of the present disclosure.

FIGS. 8A-8K illustrate a fabrication process for forming an exemplary 3D memory device, according to various embodiments of the present disclosure.

FIG. 9 illustrates a flowchart for forming an exemplary 3D memory device, according to various embodiments of the present disclosure.

FIG. 10 illustrates a flowchart for forming an exemplary 3D memory device, according to various embodiments of the present disclosure.

FIG. 11 illustrates a block diagram of an exemplary system having a 3D memory device, according to some implementations of the present disclosure.

FIG. 12A illustrates a diagram of an exemplary memory card having a 3D memory device, according to some implementations of the present disclosure.

FIG. 12B illustrates a diagram of an exemplary solid-state drive (SSD) having a 3D memory device, according to some implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures, or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon (e.g., single crystalline silicon, c-Si), silicon germanium (SiGe), gallium arsenide (GaAs), germanium (Ge), silicon on insulator (SOI), or any other suitable materials. Alternatively, the substrate can be made from an electrically non-conductive material, such as a glass, a plastic, or a sapphire wafer.

As used herein, the term “x-,” “y-,” and “z-,” axes are used herein to illustrate the spatial relationships of the components in the 3D memory device according to some implementation of the present disclosure. Substrate may include two lateral surfaces extending laterally in the x-y plane: a front surface on the front side of the wafer, and a back surface on the backside opposite to the front side of the wafer. The x- and y-directions are two orthogonal directions in the wafer plane: x-direction is the word line extending direction, and the y-direction is the bit line extending direction. The z-axis is perpendicular to both the x- and y-axes.

As used herein, whether one component (e.g., a layer or a device) is “on,” “above,” or “below” another component (e.g., a layer or a device) of a semiconductor device (e.g., 3D memory device) is determined relative to the substrate of the semiconductor device (e.g., substrate) in the z-direction (the vertical direction perpendicular to the x-y plane) when the substrate is positioned in the lowest plane of the semiconductor device in the z-direction. The same notion for describing spatial relationships is applied throughout the present disclosure.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., +10%, +20%, or +30% of the value).

As used herein, the term “3D memory device” refers to a semiconductor device with memory cell transistors on a laterally-oriented substrate so that the memory cells extend in the vertical direction with respect to the substrate. As used herein, the term “vertical/vertically” means nominally perpendicular to the lateral surface of a substrate.

As used herein, a “string” refers to the physical location/area where a memory string is located. Memory cells in a memory string may be located in a corresponding string of the 3D memory device. As used herein, the term “dielectric string” refers to one or more rows of channel structures before a gate-replacement process to form a plurality of conductive layers (e.g., word lines).

In some 3D memory devices, memory cells for storing data are vertically stacked through a stacked storage structure (e.g., a memory stack). Word line contacts are formed to be in contact with different portions of the memory cells such that a voltage can be applied to a respective portion of memory cells. By applying voltages on respective portions of the memory cells, memory blocks, memory fingers, and memory strings can be separately controlled to implement block control, finger control, and string control. Different memory blocks, memory fingers, and memory strings can be controlled to perform operations such as write, erase, read, etc.

With the development of three-dimensional (3D) memory devices, such as 3D NAND Flash memory devices, the more memory structures being stacked, the deeper trenches are required to form gate line slits or channels (e.g., memory channels or dummy channels) in the memory stacks. For a gate replacement process, the staircase regions (SS) of 3D memory device are etched to remove parts of interleaved dielectric layers and sacrificial layers to form trenches. These trenches are then filled with etch-stop materials such that the sacrificial layers are removed until the etch-stop materials. The vacancy of the sacrificial layers being removed is then filled with conductive materials to form conductive layers (e.g., word lines). However, due to more memory structures being stacked, it does not have sufficient support when doing gate replacement because the vacancy may collapse during the process. Therefore, supporting structures may be needed to sustain the entire stack structures of the memory device when performing the gate replacement process.

To address one or more of the aforementioned issues, the present disclosure introduces solutions in which different types of supporting structures and dummy channel structures for supporting may be used to support the stack structure when performing the gate replacement process, and methods of forming these supporting structures and dummy channel structures are provided. By using different types of supporting structures and dummy channel structures for supporting accordingly, it significantly reduces the stresses of the stack structures and area consumption during the gate replacement process, thereby lowering the cost and increasing the yield rate of the process.

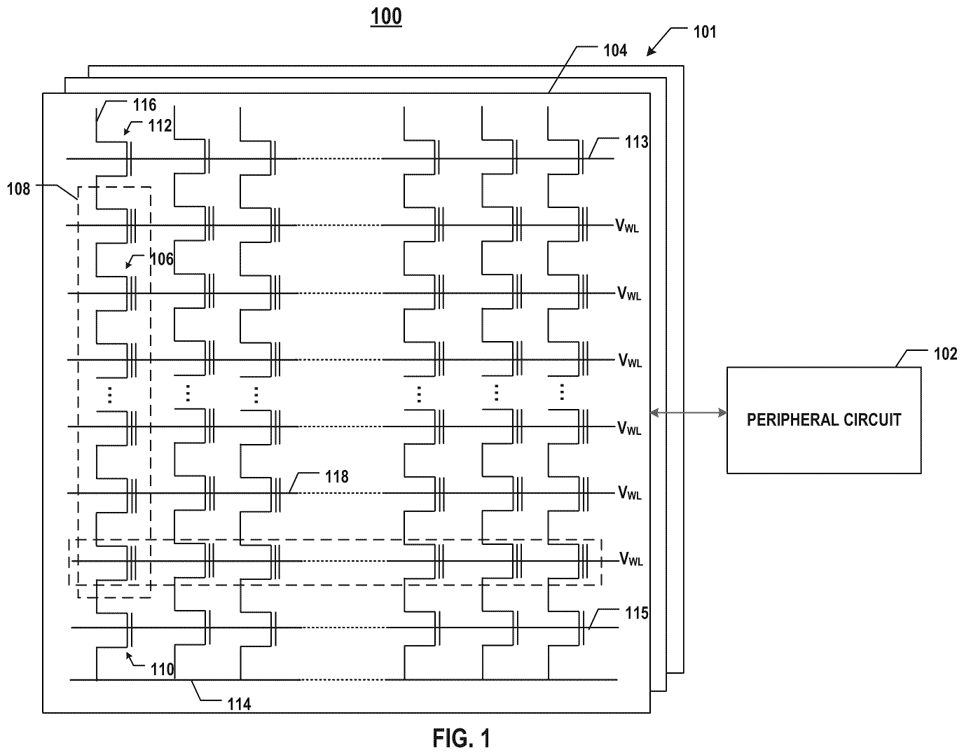

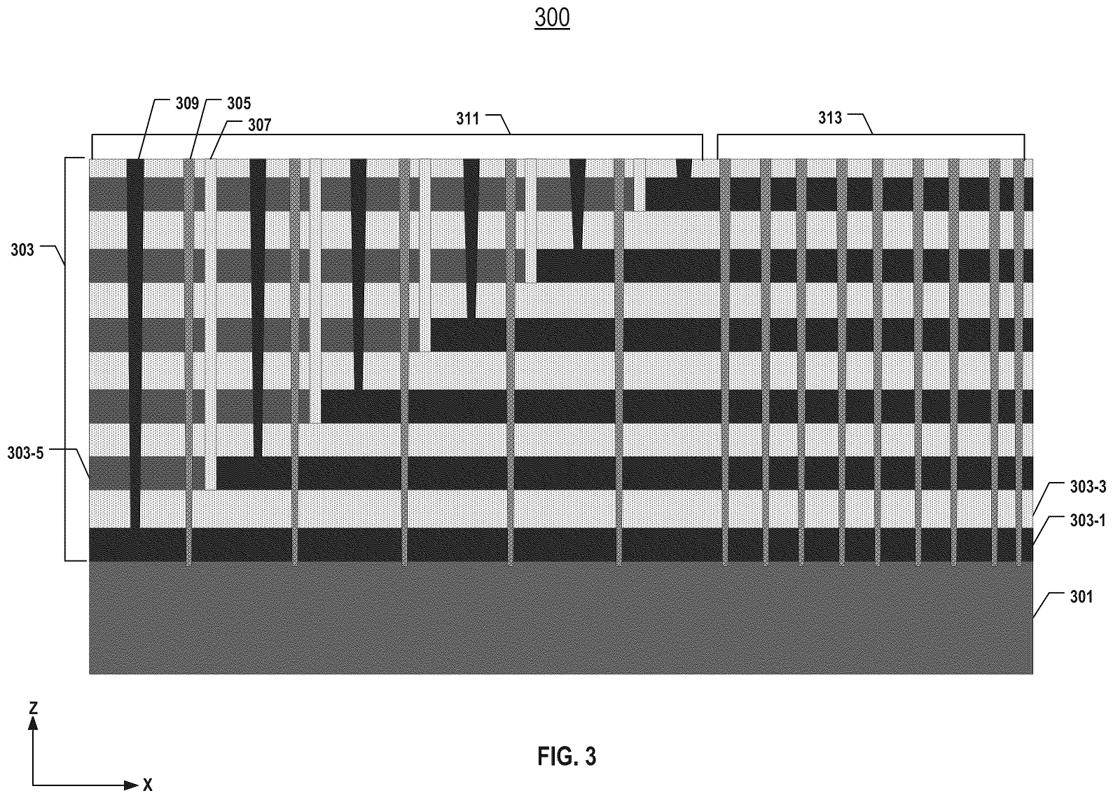

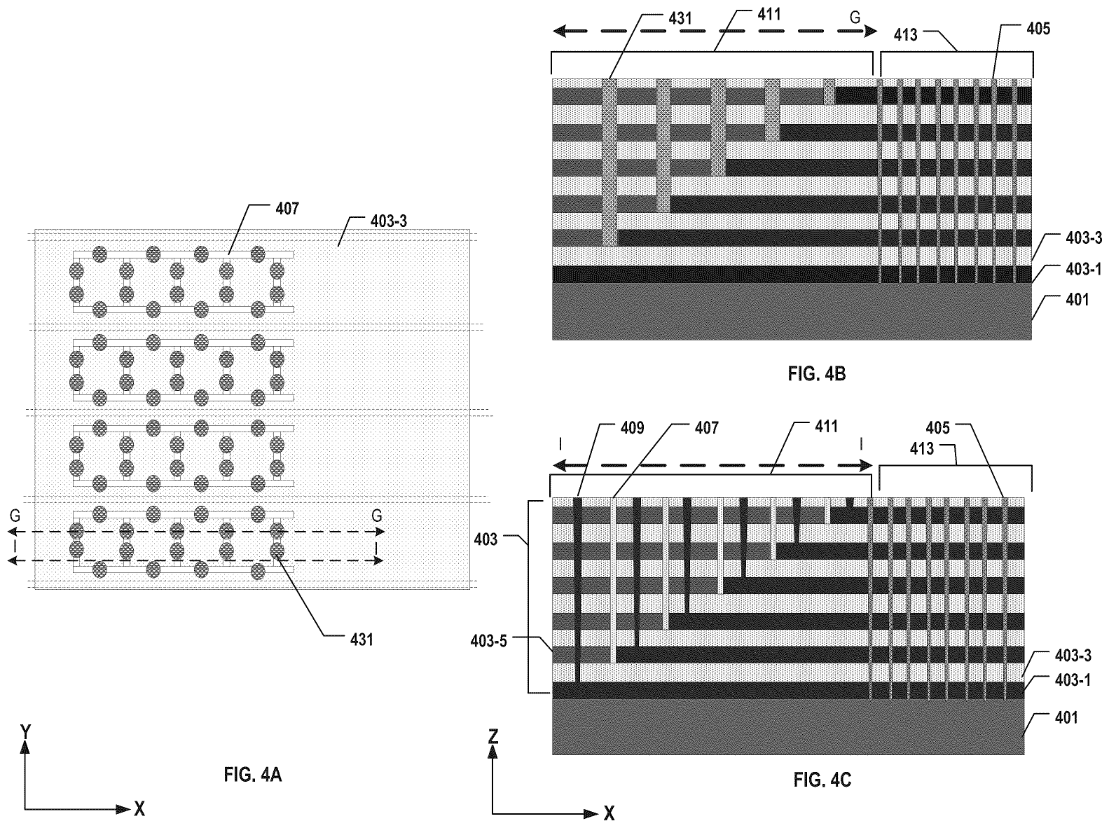

FIG. 1 illustrates a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of 3D NAND memory strings 108 each extending vertically above a substrate (not shown). In some implementations, each 3D NAND memory string 108 includes a plurality of memory cells 106 coupled in series and stacked vertically. Each memory cell 106 can hold a continuous, analog value, such as an electrical voltage or charge, that depends on the number of electrons trapped within a region of memory cell 106. Each memory cell 106 can be either a floating gate type of memory cell including a floating-gate transistor or a charge trap type of memory cell including a charge-trap transistor. Each array of 3D NAND memory strings 108 can include one or more 3D memory devices. For example, FIG. 3 illustrates an exemplary 3D memory device 300, and FIGS. 4A-4C illustrate some exemplary 3D memory device 400.

In some implementations, each memory cell 106 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than a single bit of data in four or more memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 1, each 3D NAND memory string 108 can include a source select gate (SSG) transistor 110 at its source end and a drain select gate (DSG) transistor 112 at its drain end. SSG transistor 110 and DSG transistor 112 can be configured to activate selected 3D NAND memory strings 108 (columns of the array) during read and program operations. In some implementations, the sources of SSG transistors 110 of 3D NAND memory strings 108 in the same block 104 are coupled through a same source line (SL) 114, e.g., a common SL, for example, to the ground. DSG transistor 112 of each 3D NAND memory string 108 is coupled to a respective bit line 116 from which data can be read or programmed via an output bus (not shown), according to some implementations. In some implementations, each 3D NAND memory string 108 is configured to be selected or unselected by applying a select signal (e.g., a select voltage above the threshold voltage of DSG transistor 112) or a deselect signal (e.g., a deselect voltage such as 0 V) to respective DSG transistor 112 through one or more DSG lines 113 and/or by applying a select voltage (e.g., above the threshold voltage of SSG transistor 110) or a deselect voltage (e.g., 0 V) to respective SSG transistor 110 through one or more SSG lines 115.

As shown in FIG. 1, 3D NAND memory strings 108 can be organized into multiple blocks 104, each of which can have a common source line 114. In some implementations, each block 104 is the basic data unit for erase operations, i.e., all memory cells 106 on the same block 104 are erased at the same time. Memory cells 106 can be coupled through word lines 118 that select which row of memory cells 106 is affected by read and program operations. In some implementations, each word line 118 is coupled to a row of memory cells 106, which is the basic data unit for program and read operations. Each word line 118 can be coupled to a plurality of control gates (gate electrodes) at each memory cell 106 in respective row and a gate line coupling the control gates.

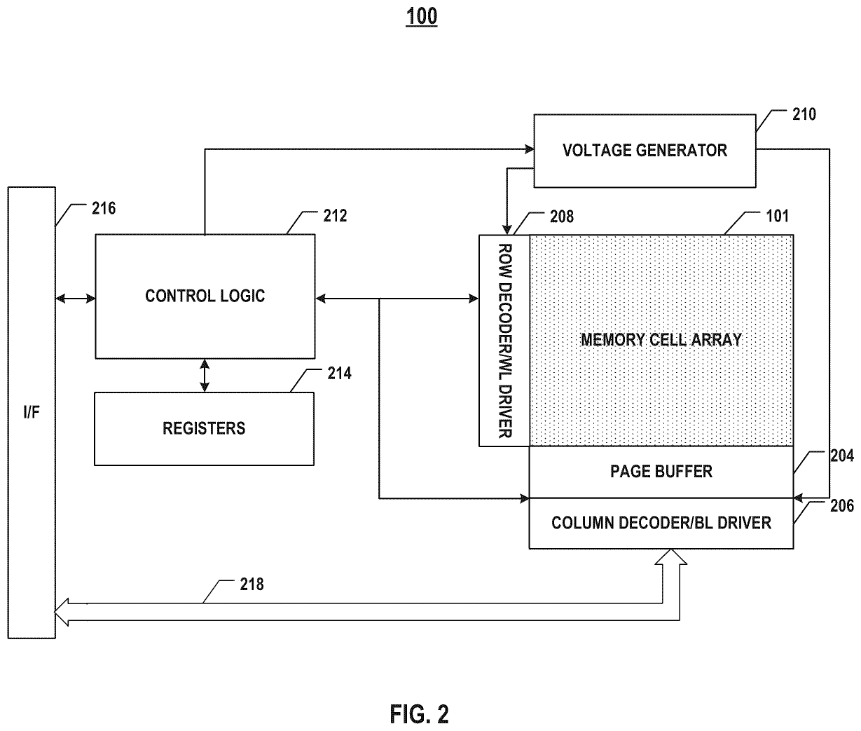

Peripheral circuits 102 can be coupled to memory cell array 101 through bit lines 116, word lines 118, source lines 114, SSG lines 115, and DSG lines 113. As described above, peripheral circuits 102 can include any suitable circuits for facilitating the operations of memory cell array 101 by applying and sensing voltage signals and/or current signals through bit lines 116 to and from each target memory cell 106 through word lines 118, source lines 114, SSG lines 115, and DSG lines 113. Peripheral circuits 102 can include various types of peripheral circuits formed using complementary metal-oxide semiconductor (CMOS) technologies. For example, FIG. 2 illustrates some exemplary peripheral circuits 102 including a page buffer 204, a column decoder/bit line driver 206, a row decoder/word line driver 208, a voltage generator 210, control logic 212, registers 214, an interface (I/F) 216, and a data bus 218. It is understood that in some examples, additional peripheral circuits 102 may be included as well.

Page buffer 204 can be configured to buffer data read from or programmed to memory cell array 101 according to the control signals of control logic 212. In one example, page buffer 204 may store one page of program data (write data) to be programmed into one row of memory cell array 101. In another example, page buffer 204 also performs program verify operations to ensure that the data has been properly programmed into memory cells 106 coupled to selected word lines 118.

Row decoder/word line driver 208 can be configured to be controlled by control logic 212 and select or unselect a block 104 of memory cell array 101 and select or unselect a word line 118 of selected block 104. Row decoder/word line driver 208 can be further configured to drive memory cell array 101. For example, row decoder/word line driver 208 may drive memory cells 106 coupled to the selected word line 118 using a word line voltage generated from voltage generator 210. In some implementations, row decoder/word line driver 208 can include a decoder and string drivers (driving transistors) coupled to local word lines and word lines 118.

Voltage generator 210 can be configured to be controlled by control logic 212 and generate the word line voltages (e.g., read voltage, program voltage, pass voltage, local voltage, and verification voltage) to be supplied to memory cell array 101. In some implementations, voltage generator 210 is part of a voltage source that provides voltages at various levels of different peripheral circuits 102 as described below in detail. Consistent with the scope of the present disclosure, in some implementations, the voltages provided by voltage generator 210, for example, to row decoder/word line driver 208 and page buffer 204 are above certain levels that are sufficient to perform the memory operations. For example, the voltages provided to page buffer 204 may be between 2 V and 3.3 V, such as 3.3 V, and the voltages provided to row decoder/word line driver 208 may be greater than 3.3 V, such as between 3.3 V and 30 V.

Column decoder/bit line driver 206 can be configured to be controlled by control logic 212 and select one or more 3D NAND memory strings 108 by applying bit line voltages generated from voltage generator 210. For example, column decoder/bit line driver 206 may apply column signals for selecting a set of N bits of data from page buffer 204 to be outputted in a read operation.

Control logic 212 can be coupled to each peripheral circuit 102 and configured to control operations of peripheral circuits 102. Registers 214 can be coupled to control logic 212 and include status registers, command registers, and address registers for storing status information, command operation codes (OP codes), and command addresses for controlling the operations of each peripheral circuit 102.

Interface 216 can be coupled to control logic 212 and configured to interface memory cell array 101 with a memory controller (not shown). In some implementations, interface 216 acts as a control buffer to buffer and relay control commands received from the memory controller and/or a host (not shown) to control logic 212 and status information received from control logic 212 to the memory controller and/or the host. Interface 216 can also be coupled to page buffer 204 and column decoder/bit line driver 206 via data bus 218 and act as an Input/Output (I/O) interface and a data buffer to buffer and relay the program data received from the memory controller and/or the host to page buffer 204 and the read data from page buffer 204 to the memory controller and/or the host. In some implementations, interface 216 and data bus 218 are part of an I/O circuit of peripheral circuits 102.

FIG. 3 illustrates a cross-sectional view of an exemplary 3D memory device 300 (corresponding to the 3D memory device in memory cell array 101), according to some implementations of the present disclosure. 3D memory device 300 may include one or more memory blocks. Each memory block may include one or more core regions 313 and one or more staircase regions 311 adjacent to core regions 313 in a first direction (e.g., x-direction or a first lateral direction). Each memory block in each core region 313 may include one or more memory strings (e.g., corresponding to 3D NAND memory strings 108 in FIG. 1) extending in a second direction (e.g., a z-direction or a vertical direction) perpendicular to the first direction. One or more memory channel structures may be formed in each memory block. The intersections of the memory channel structures and the word lines (or conductive layers) may form one or more memory cells in the memory blocks/strings.

In some implementations, each of the memory channel structures formed in core regions 313 may include a channel hole filled with a semiconductor layer (e.g., as a semiconductor channel) and a composite dielectric layer (e.g., as a memory film). In some implementations, the semiconductor channel includes silicon, such as amorphous silicon, polysilicon, or single crystalline silicon. In some implementations, the memory film is a composite layer including a tunneling layer, a storage layer (also known as a “charge trap layer”), and a blocking layer. The remaining space of the memory channel structure can be partially or fully filled with a capping layer including dielectric materials, such as silicon oxide, and/or an air gap. The memory channel structure can have a cylinder shape (e.g., a pillar shape). The capping layer, the semiconductor channel, the tunneling layer, the storage layer, and the blocking layer of the memory film are arranged radially from the center toward the outer surface of the pillar in this order, according to some implementations. The tunneling layer can include silicon oxide, silicon oxynitride, or any combination thereof. The storage layer can include silicon nitride, silicon oxynitride, silicon, or any combination thereof. The blocking layer can include silicon oxide, silicon oxynitride, high-k dielectrics, or any combination thereof. In one example, the memory film can include a composite layer of silicon oxide/silicon oxynitride/silicon oxide (ONO).

In some embodiments, the memory channel structure further includes a channel plug (not shown) in the top portion (e.g., at the upper end) of the memory channel structure. As used herein, the “upper end” of a component (e.g., the memory channel structure) is the end farther away from a substrate in the z-direction, and the “lower end” of the component (e.g., the memory channel structure) is the end closer to the substrate in the z-direction when the substrate is positioned in the lowest plane of 3D memory device 300. The channel plug can include semiconductor materials (e.g., polysilicon). In some embodiments, the channel plug functions as the drain of the NAND memory string.

3D memory device 300 includes a semiconductor layer 301 (e.g., a substrate or a later-formed layer after removing the substrate), and a stack structure 303 of interleaved dielectric layers 303-3 and conductive layers 303-1 formed on semiconductor layer 301. In some implementations, stack structure 303 further includes interleaved dielectric layers 303-3 and sacrificial layers 303-5 formed in staircase region 311 of stack structure 303. In some implementations, a material of conductive layer 303-1 includes tungsten (W), cobalt (Co), copper (Cu), aluminum (Al), polycrystalline silicon (polysilicon), doped silicon, silicides, or any combination thereof. In some implementations, a material of dielectric layer 303-3 includes dielectric materials including, but not limited to, silicon oxide, silicon nitride, silicon oxynitride, or any combination thereof. In some implementations, a material of sacrificial layers 303-5 includes dielectric materials including, but not limited to, silicon oxide, silicon nitride, silicon oxynitride, or any combination thereof. However, to selectively etch to remove sacrificial layers 303-5 and retain dielectric layer 303-3, a material of dielectric layer 303-3 and that of sacrificial layers 303-5 are different materials. For instance, in some implementations, dielectric layer 303-3 may be silicon oxide, and sacrificial layers 303-5 may be silicon nitride.

3D memory device 300 may further include one or more first supporting structures 305 formed in staircase region 311 and core region 313. Each first supporting structure 305 extends into stack structure 303 in the z-direction and may be in contact with semiconductor layer 301. In some implementations, first supporting structures 305 may be dummy channel structures. In some implementations, first supporting structures 305 may be suitable dielectric materials including, but not limited to, silicon oxide, silicon nitride, silicon oxynitride, or any combination thereof.

In some implementations, staircase region 311 may be in the center of stack structure 303, and core region 313 may be at two sides of staircase region 311 of stack structure 303 in the x-direction (e.g., the word line direction). In another implementation, the core region may be in the center of the stack structure, while the staircase region may be at two sides of the core region of the stack structure in the x-direction (e.g., the word line direction).

3D memory device 300 may further include one or more etch stop structures 307 formed in staircase region 311 of stack structure 303 and extending into stack structure 303 in the z-direction. In some implementations, each etch stop structure 307 is in contact with corresponding conductive layer 303-1. In some implementations, each etch stop structure 307 is formed between a corresponding conductive layer 303-1 and sacrificial layer 303-5 in a lateral direction (e.g., x-direction or y-direction). In some implementations, each etch stop structure 307 includes a material that cannot be removed or relatively slowly removed by an etching solvent of sacrificial layer 303-5. In some implementations, a material of etch stop structure 307 includes dielectric materials including, but not limited to, silicon oxide, silicon nitride, silicon oxynitride, or any combination thereof. For instance, in some implementations, etch stop structure 307 may include silicon oxide.

3D memory device 300 may further include one or more contact structures 309 formed in staircase region 311 of stack structure 303 and extending into stack structure 303 in the z-direction. In some implementations, each of contact structures 309 is formed on top of and in contact with corresponding conductive layer 303-1. In some implementations, a material of contact structures 309 includes tungsten (W), cobalt (Co), copper (Cu), aluminum (Al), polycrystalline silicon (polysilicon), doped silicon, silicides, or any combination thereof.

FIG. 4A illustrates a schematic top view of an exemplary 3D memory device 400 (corresponding to the 3D memory device in memory cell array 101) and FIGS. 4B-4C illustrate cross-sectional views of the exemplary 3D memory device 400. FIG. 4B is a cross-sectional view of FIG. 4A along G-G plane while FIG. 4C is a cross-sectional view of FIG. 4A along I-I plane. It is noted that FIG. 4A only illustrates a schematic top view of the exemplary 3D memory device 400. That is, some elements (e.g., contact structures, supporting structures, etc.) shown in FIGS. 4B-4C may be omitted in FIG. 4A.

As shown in FIG. 4C, 3D memory device 400 may include one or more memory blocks. Each memory block may include one or more core regions 413 and one or more staircase regions 411 adjacent to core regions 413 in a first direction (e.g., x-direction or a first lateral direction). Each memory block in each core region 413 may include one or more memory strings (e.g., corresponding to 3D NAND memory strings 108 in FIG. 1) extending in a second direction (e.g., a z-direction or a vertical direction) perpendicular to the first direction. One or more memory channel structures may be formed in each memory block. The intersection of the memory channel structures and the word lines (or conductive layers) may form one or more memory cells in the memory blocks/strings.

In some implementations, each of the memory channel structures formed in core regions 413 may include a channel hole filled with a semiconductor layer (e.g., as a semiconductor channel) and a composite dielectric layer (e.g., as a memory film). In some implementations, the semiconductor channel includes silicon, such as amorphous silicon, polysilicon, or single crystalline silicon. In some implementations, the memory film is a composite layer including a tunneling layer, a storage layer (also known as a “charge trap layer”), and a blocking layer. The remaining space of the memory channel structure can be partially or fully filled with a capping layer including dielectric materials, such as silicon oxide, and/or an air gap. The memory channel structure can have a cylinder shape (e.g., a pillar shape). The capping layer, the semiconductor channel, the tunneling layer, the storage layer, and the blocking layer of the memory film are arranged radially from the center toward the outer surface of the pillar in this order, according to some implementations. The tunneling layer can include silicon oxide, silicon oxynitride, or any combination thereof. The storage layer can include silicon nitride, silicon oxynitride, silicon, or any combination thereof. The blocking layer can include silicon oxide, silicon oxynitride, high-k dielectrics, or any combination thereof. In one example, the memory film can include a composite layer of silicon oxide/silicon oxynitride/silicon oxide (ONO).

In some embodiments, the memory channel structure further includes a channel plug (not shown) in the top portion (e.g., at the upper end) of the memory channel structure. As used herein, the “upper end” of a component (e.g., the memory channel structure) is the end farther away from a semiconductor layer in the z-direction, and the “lower end” of the component (e.g., the memory channel structure) is the end closer to the semiconductor layer in the z-direction when the semiconductor layer is positioned in the lowest plane of 3D memory device 400. The channel plug can include semiconductor materials (e.g., polysilicon). In some embodiments, the channel plug functions as the drain of the NAND memory string.

3D memory device 400 includes a semiconductor layer 401, and a stack structure 403 of interleaved dielectric layers 403-3 and conductive layers 403-1 formed on semiconductor layer 401. In some implementations, stack structure 403 further includes interleaved dielectric layers 403-3 and sacrificial layers 403-5 formed in staircase region 411 of stack structure 403. In some implementations, a material of conductive layer 403-1 includes tungsten (W), cobalt (Co), copper (Cu), aluminum (Al), polycrystalline silicon (polysilicon), doped silicon, silicides, or any combination thereof. In some implementations, a material of dielectric layer 403-3 includes dielectric materials including, but not limited to, silicon oxide, silicon nitride, silicon oxynitride, or any combination thereof. In some implementations, a material of sacrificial layers 403-5 includes dielectric materials including, but not limited to, silicon oxide, silicon nitride, silicon oxynitride, or any combination thereof. However, to selectively etch to remove sacrificial layers 403-5 and retain dielectric layer 403-3, a material of dielectric layer 403-3 and that of sacrificial layers 403-5 are different materials. For instance, in some implementations, dielectric layer 403-3 may be silicon oxide, and sacrificial layers 403-5 may be silicon nitride.

3D memory device 400 may further include one or more first supporting structures 405 formed in core region 413. Each first supporting structure 405 extends into stack structure 403 in the z-direction and may be in contact with semiconductor layer 401. In some implementations, first supporting structures 405 may be dummy channel structures. In some implementations, first supporting structures 405 may be suitable dielectric materials including, but not limited to, silicon oxide, silicon nitride, silicon oxynitride, or any combination thereof.

In some implementations, staircase region 411 may be in the center of stack structure 403, and core region 413 may be at two sides of staircase region 411 of stack structure 403 in the x-direction (e.g., the word line direction). In another implementation, the core region may be in the center of the stack structure, while the staircase region may be at two sides of the core region of the stack structure in the x-direction (e.g., the word line direction).

3D memory device 400 may further include one or more etch stop structures 407 formed in staircase region 411 of stack structure 403 and extending into stack structure 403 in the z-direction. In some implementations, each etch stop structure 407 is in contact with corresponding conductive layer 403-1. In some implementations, each etch stop structure 407 is formed between a corresponding conductive layer 403-1 and sacrificial layer 403-5 in a lateral direction (e.g., x-direction or y-direction). In some implementations, each etch stop structure 407 includes a material that cannot be removed or relatively slowly removed by an etching solvent of sacrificial layer 403-5. In some implementations, a material of etch stop structure 407 includes dielectric materials including, but not limited to, silicon oxide, silicon nitride, silicon oxynitride, or any combination thereof. For instance, in some implementations, etch stop structure 407 may include silicon oxide.

3D memory device 400 may further include one or more contact structures 409 formed in staircase region 411 of stack structure 403 and extending into stack structure 403 in the z-direction. In some implementations, each contact structure 409 is formed on top of and in contact with corresponding conductive layer 403-1. In some implementations, a material of contact structures 409 includes tungsten (W), cobalt (Co), copper (Cu), aluminum (Al), polycrystalline silicon (polysilicon), doped silicon, silicides, or any combination thereof.

Also, as shown in FIGS. 4A and 4B, 3D memory device 400 may further include one or more second supporting structures 431 formed in staircase region 411. Each second supporting structure 431 extends into stack structure 403 in the z-direction and may be in contact with semiconductor layer 401. In some implementations, second supporting structures 431 may be dummy channel structures. In some implementations, second supporting structures 431 may be suitable dielectric materials including, but not limited to, silicon oxide, silicon nitride, silicon oxynitride, or any combination thereof. In some implementations, each second supporting structure 431 has a round shape in a top view and has a diameter more than that of etch stop structure 407. In some implementations, each of second supporting structures 431 is arranged between adjacent etch stop structures 407. In some implementations, second supporting structures 431 are arranged along the extending lateral direction (e.g., in x-direction or y-direction) of etch stop structure 407. As long as each of second supporting structures 431 is adjacent to etch stop structure 407 or over where etch stop structure 407 is originally formed, the area consumption of supporting structures may be minimized, thereby increasing the overall performance of 3D memory device 400. In some implementations, second supporting structures 431 may be suitable dielectric materials including, but not limited to, silicon oxide, silicon nitride, silicon oxynitride, or any combination thereof.

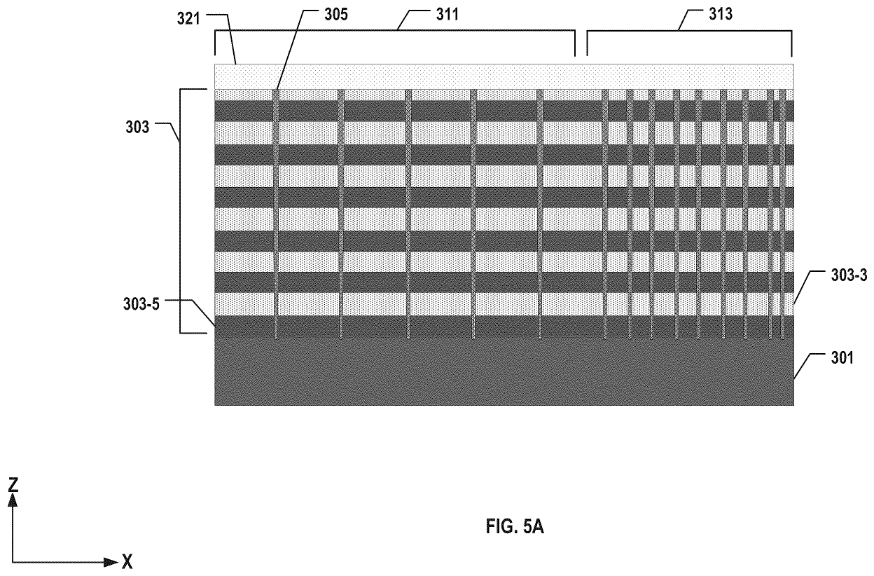

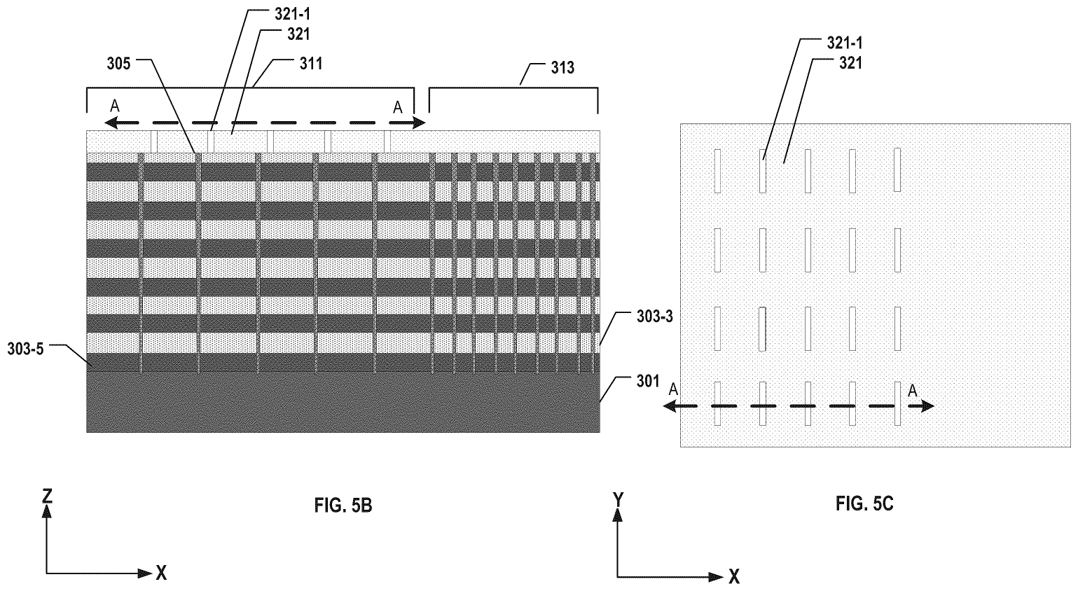

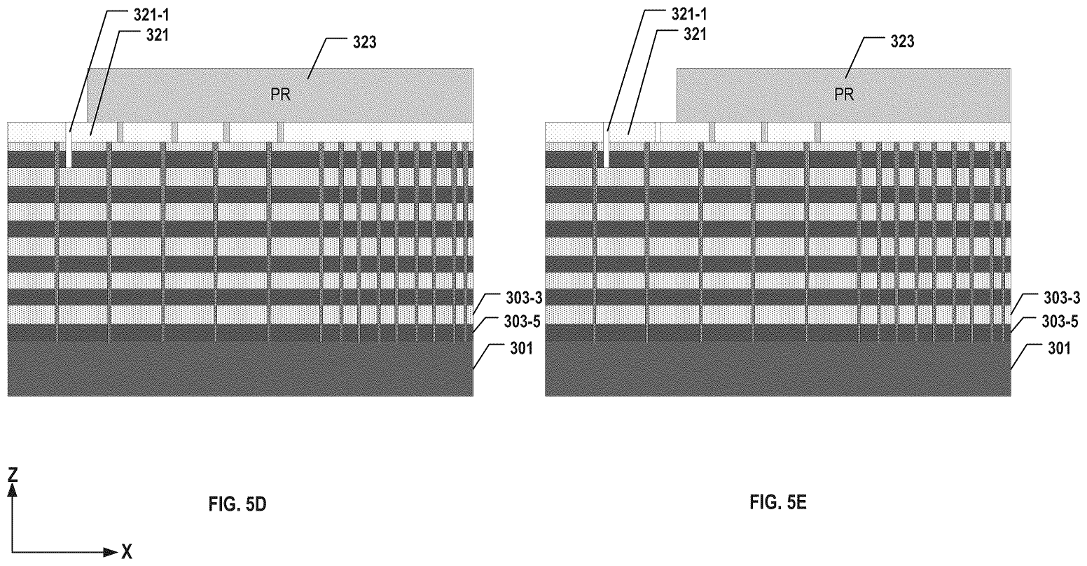

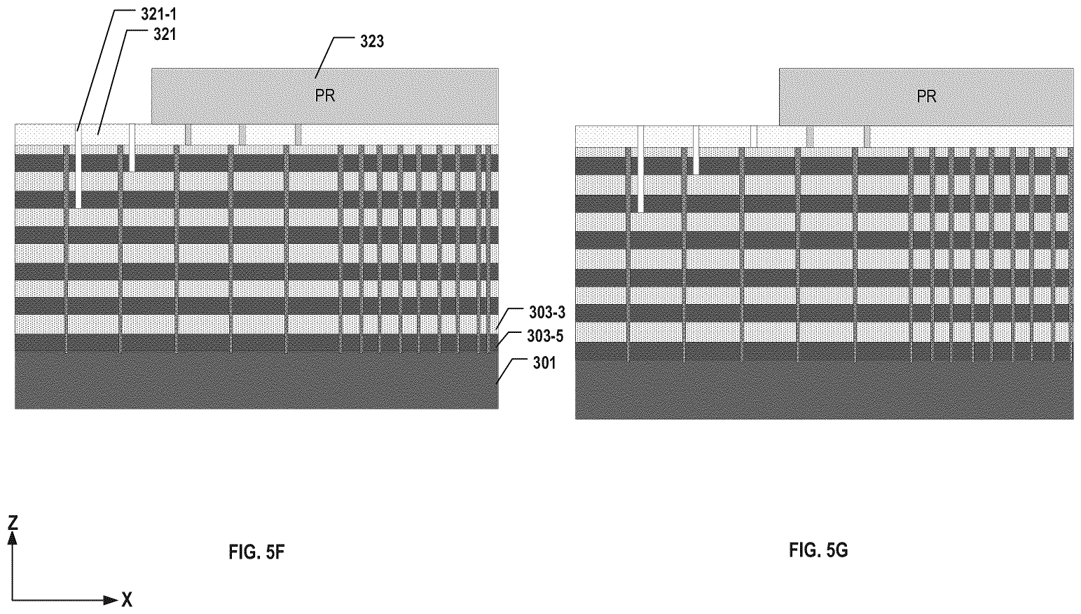

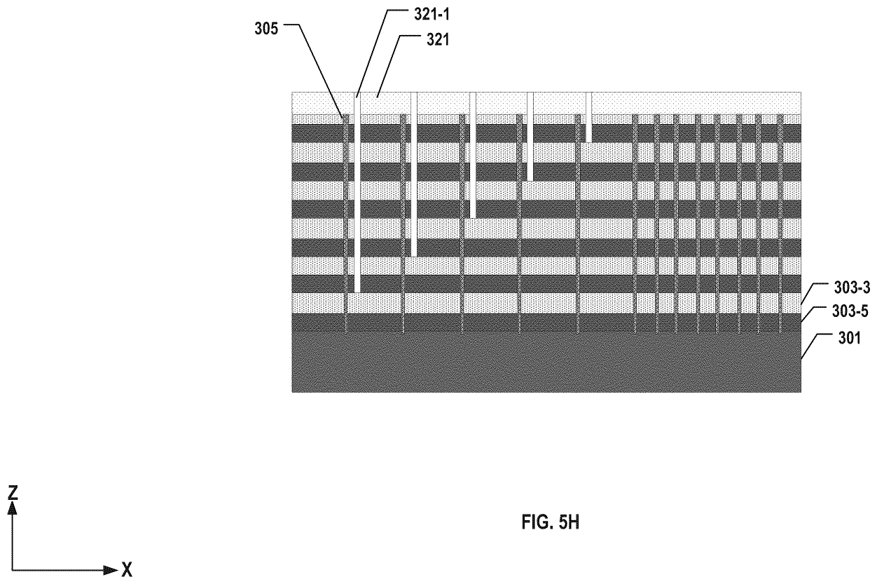

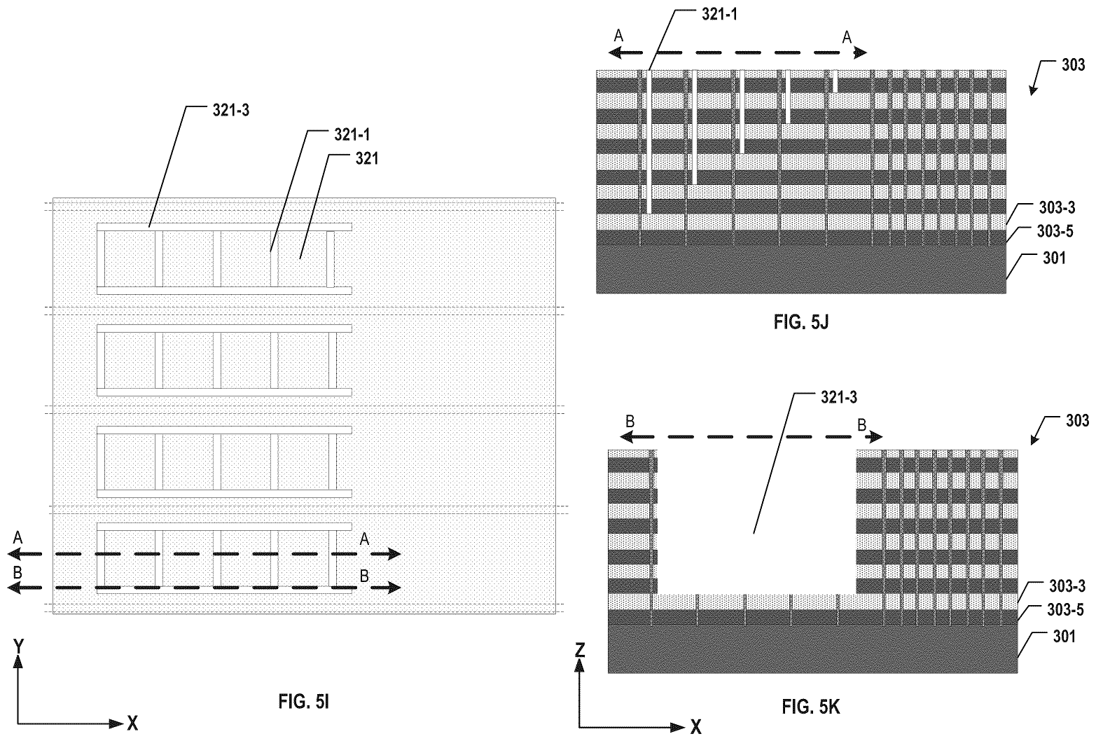

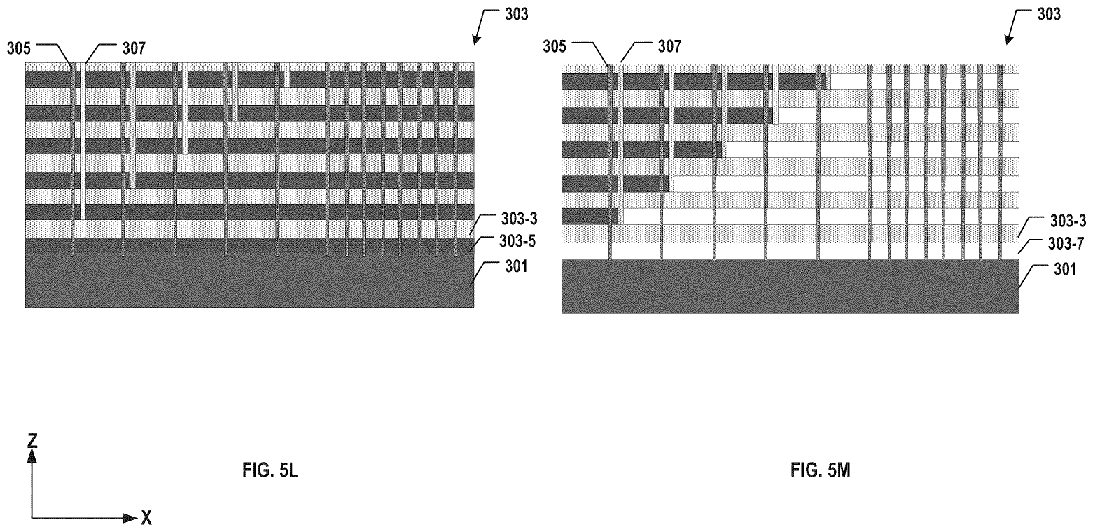

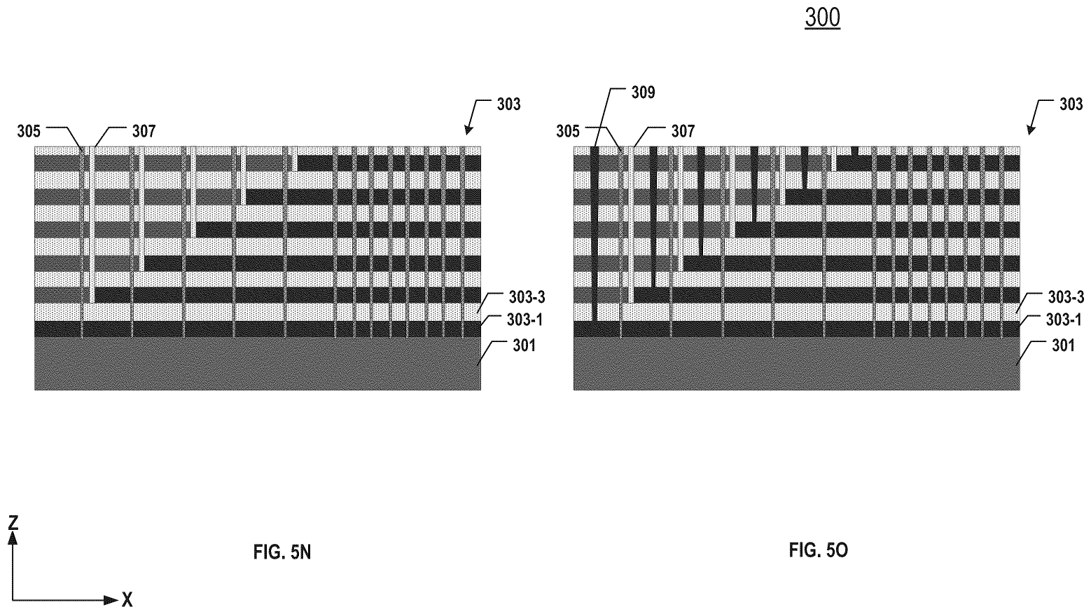

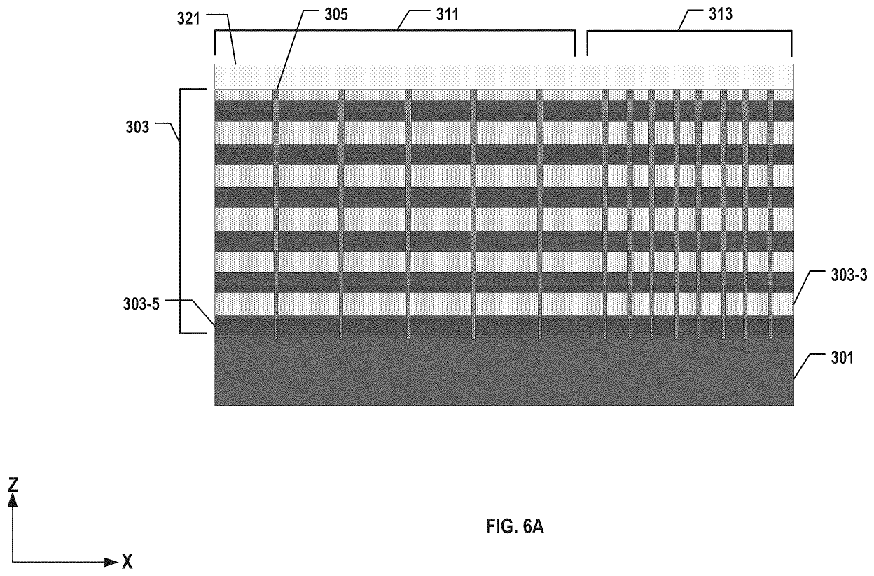

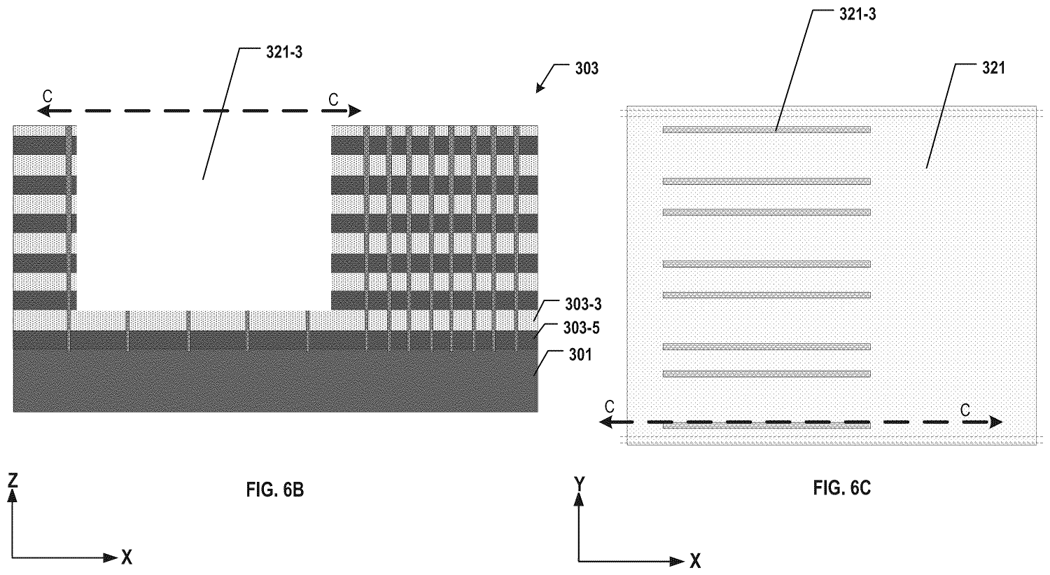

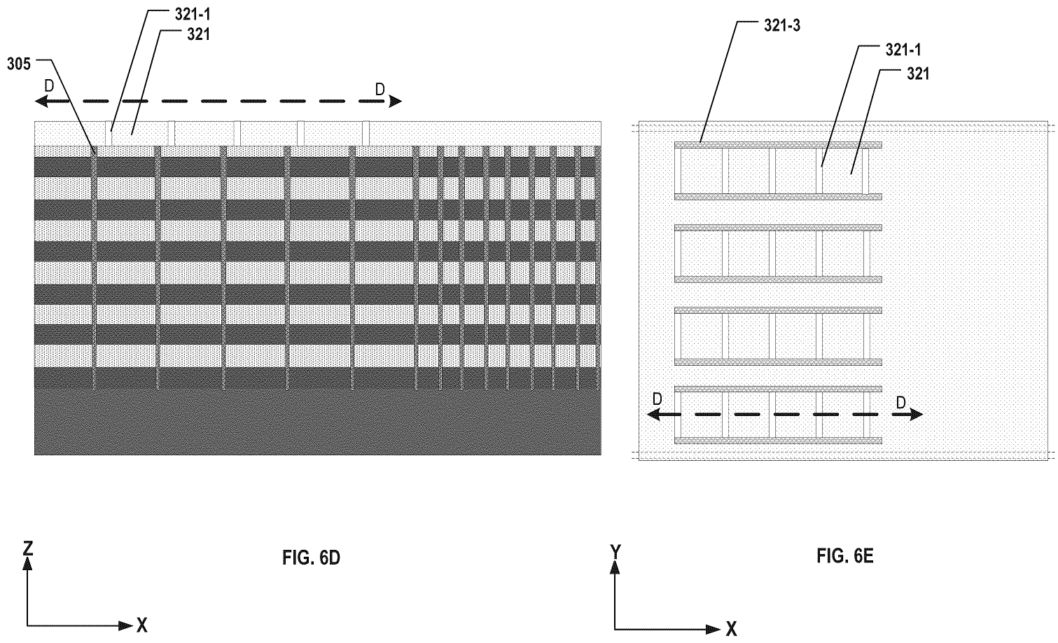

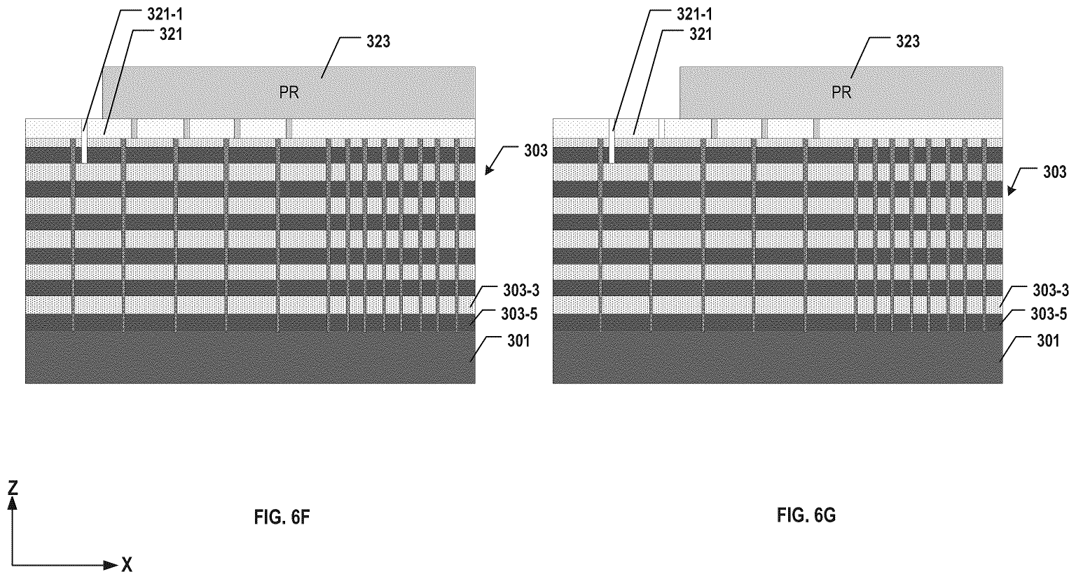

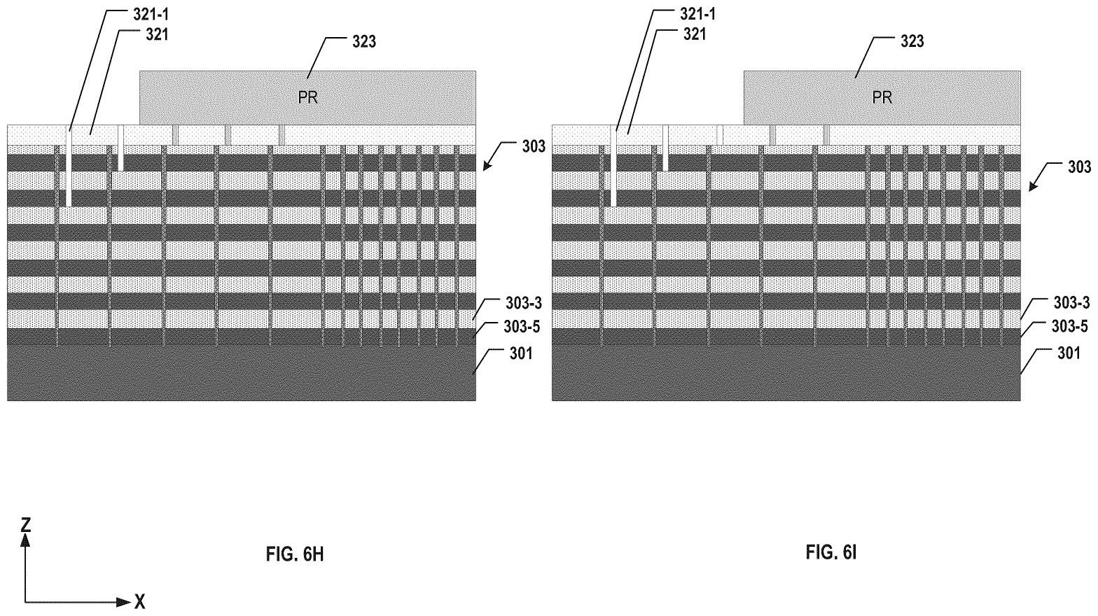

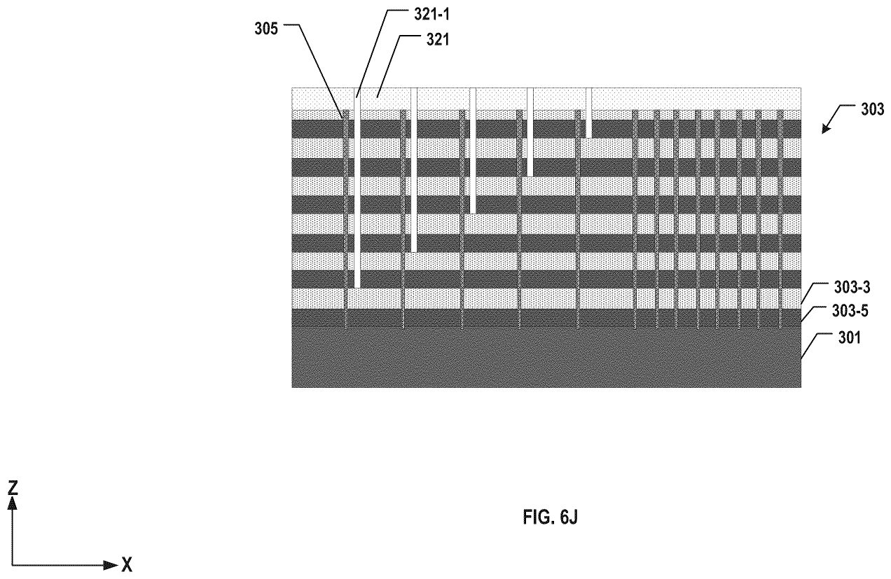

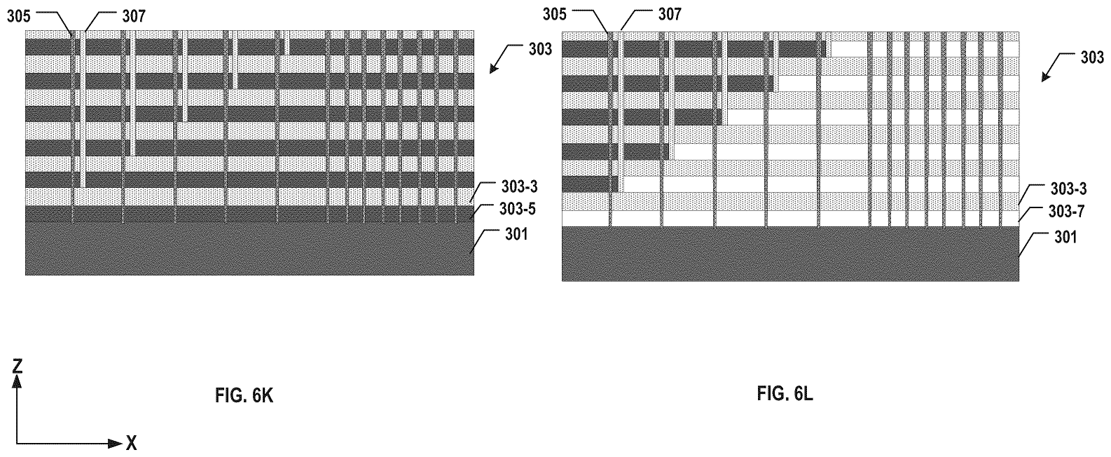

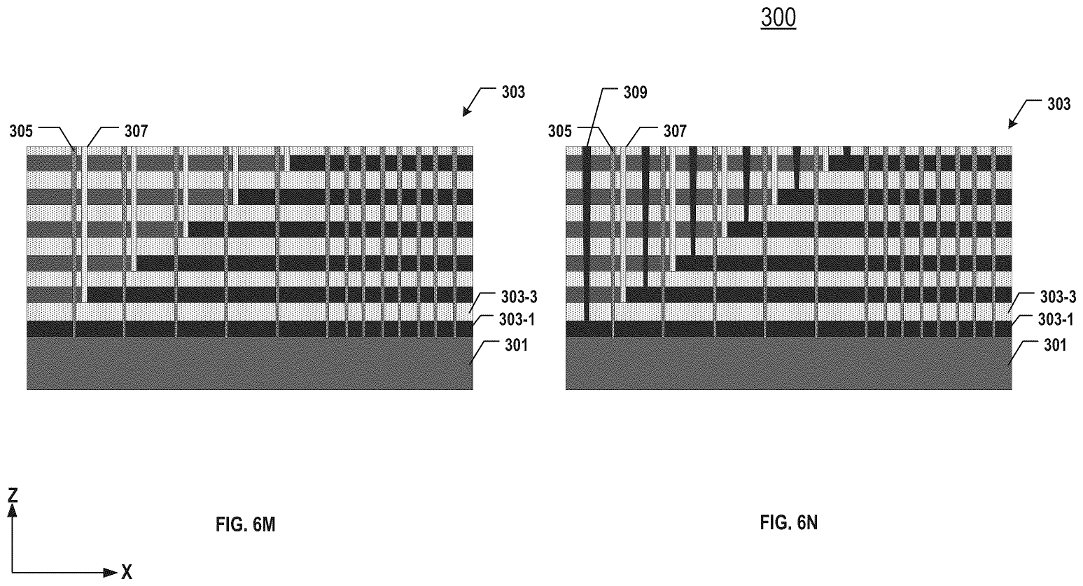

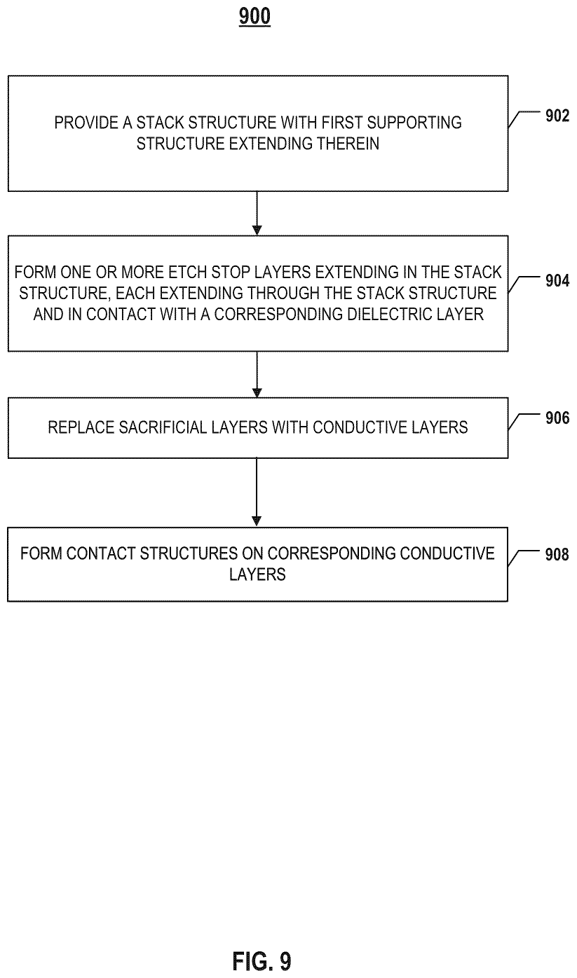

FIGS. 5A-5O illustrate a fabrication process for forming an exemplary 3D memory device, according to various embodiments of the present disclosure. FIG. 9 is a flowchart of a method 900 for forming the exemplary 3D memory device. It is understood that the operations shown in method 900 are not exhaustive and that other operations can be performed as well before, after, or between any of the illustrated operations. Further, some of the operations may be performed simultaneously, or in a different order than shown in FIGS. 5A-5O. It can also be the process flow as shown in FIGS. 6A-6N, or 7A-7N, which will be discussed later.

Referring to FIG. 9, method 900 starts at operation 902, in which a stack structure with one or more first supporting structures extending therein is formed. FIG. 5A illustrates a corresponding structure.

As shown in FIG. 5A, semiconductor layer 301 is provided, and stack structure 303 including interleaved dielectric layers 303-3 and sacrificial layers 303-5 are formed on semiconductor layer 301. After forming stack structure 303, one or more first supporting structures 305 are formed on semiconductor layer 301 and extend in staircase region 311 and core region 313 of stack structure 303 in the z-direction. First supporting structures 305 may be provided by forming one or more through holes by an etching process (e.g., wet etching, dry etching, or a combination thereof) through stack structure 303, and then filling (e.g., depositing) the through holes by dielectric materials. In some implementations, first supporting structures 305 may be formed before forming stack structure 303. Next, a hard mask 321 is formed on stack structure 303. In some implementations, hard mask 321 includes dielectric materials including, but not limited to, silicon oxide, silicon nitride, silicon oxynitride, aluminum oxide, or any combination thereof. For instance, hard mask 321 may include aluminum oxide.

Referring to FIG. 9, method 900 proceeds to operation 904, in which one or more etch stop structures extending in the stack structure are provided. Each etch stop structure extends through the stack structure and is in contact with a corresponding dielectric layer. FIGS. 5B-5L illustrate corresponding structures.

FIG. 5B is a cross-sectional view of FIG. 5C along A-A plane. As shown in FIGS. 5B and 5C, hard mask 321 is partially removed to form one or more first hard mask through holes 321-1 as a pattern. In this implementation, first hard mask through holes 321-1 may extend in y-direction and may be arranged side-by-side in the x-direction. Each first hard mask through holes 321-1 represents a location of a corresponding step of steps in staircase region 311 to be etched. It is noted that the location of first hard mask through holes 321-1 may not be overlapped with that of first supporting structures 305.

Next, as shown in FIG. 5D, a photoresist layer 323 is partially formed on hard mask 321 to expose a first set of first hard mask through holes 321-1. Next, etch a first time through photoresist layer 323 via the first set of first hard mask through holes 321-1 to remove a first pair of dielectric layer 303-3 and sacrificial layer 303-5. The etching process may be done by using wet etching, dry etching, or a combination thereof. In some implementations, the etching process to remove a pair of dielectric layer 303-3 and sacrificial layer 303-5 can be done by using an “end-point” feature of etching equipment. That it, the “end-point” feature of the etching equipment may etch through stack structure 303 until a pre-determined condition is met, e.g., a pre-determined element of etching residues. For example, stack structure 303 is etched until detecting the nitride of sacrificial layer 303-5. And, after detecting that nitride concentration is higher than a pre-determined level, it will stop etching stack structure 303.

Next, as shown in FIG. 5E, after through holes penetrating the first pair of dielectric layer 303-3 and sacrificial layer 303-5 are formed, photoresist layer 323 is further partially removed (e.g., trimmed) to expose a second set of first hard mask through holes 321-1. Next, etch a second time through photoresist layer 323 via the first set of first hard mask through holes 321-1 to remove a second pair of dielectric layer 303-3 and sacrificial layer 303-5, and via the second set of first hard mask through holes 321-1 to remove a first pair of dielectric layer 303-3 and sacrificial layer 303-5, where the second pair of dielectric layer 303-3 and sacrificial layer 303-5 are one pair below the first pair of dielectric layer 303-3 and sacrificial layer 303-5. By repeating the process, as shown in FIGS. 5F-5H, each pair of dielectric layer 303-3 and sacrificial layer 303-5 has a respective first hard mask through hole 321-1 extending therein.

FIG. 5J shows a cross-sectional view of FIG. 51 along A-A plane, and FIG. 5K shows a cross-sectional view of FIG. 51 along B-B plane. Next, as shown in FIGS. 51-5K, one or more second hard mask through holes 321-3 are formed extending through stack structure 303 in the z-direction and also along the x-direction. In some implementations, each second hard mask through hole 321-3 extends in a direction perpendicular to that of first hard mask through hole 321-1. Second hard mask through holes 321-3 may extend to semiconductor layer 301 or to a pair of dielectric layer and sacrificial layer adjacent to semiconductor layer 301. The etching of second hard mask through holes 321-3 may be done by using wet etching, dry etching, or a combination thereof.

Next, after forming the hard mask through holes, as shown in FIG. 5L, etch stop materials are filled in the hard mask through holes to form one or more etch stop structures 307. Each etch stop structure 307 extends into stack structure 303 and is in contact with one of dielectric layers 303-3.

Referring to FIG. 9, method 900 proceeds to operation 906, in which sacrificial layers are replaced with conductive layers. FIGS. 5M-5N illustrate corresponding structures.

As shown in FIG. 5M, sacrificial layers (e.g., 303-5 in FIG. 5L) are partially removed until etch stop structures 307. The removal of the sacrificial layers may be wet etching, dry etching, or a combination thereof. In this implementation, the removal of the sacrificial layers is wet etching by using etching solvent that can selectively remove sacrificial layers without removing or at least hardly removing dielectric layers 303-3 and/or first supporting structures 305. After the removal of the sacrificial layers, vacancies 303-7 are left unfilled. As such, during this stage, first supporting structures 305 can provide sufficient support for stack structure 303 and prevent stack structure 303 from collapsing or cracking down.

Next, as shown in FIG. 5N, these vacancies are then filled with conductive materials to form conductive layers 303-1. In some implementations, a conductive material to form conductive layer 303-1 includes W, Co, Cu, Al, polysilicon, doped silicon, silicides, or any combination thereof. The deposition process of the conductive materials includes, atomic-layer deposition (ALD), chemical vapor deposition (CVD), physical vapor deposition (PVD), or a combination thereof.

Referring to FIG. 9, method 900 proceeds to operation 908, in which contact structures are formed on corresponding conductive layers. FIG. 5O illustrates corresponding structures.

As shown in FIG. 5O, after replacing the sacrificial layers with conductive layers, the conductive layers extend in stack structure 303 in a lateral direction to etch stop structures 307. Since each conductive layer is formed stepwise due to the forming of etch stop structures 307, contact structures 309 may be formed on and in contact with corresponding conductive layers. To form contact structures 309, another etching process may be provided to form through holes extending into stack structure 303 to the corresponding conductive layers. And then, conductive materials can be filled into these through holes to form these contact structures 309.

FIGS. 6A-6N provide another process flow for forming 3D memory device 300 which is similar to implementations in FIGS. 5A-5O. For ease of description, the same or similar processes to FIGS. 5A-5O will be omitted.

As shown in FIG. 6A, semiconductor layer 301 is provided, and stack structure 303 including interleaved dielectric layers 303-3 and sacrificial layers 303-5 are formed on semiconductor layer 301. After forming stack structure 303, one or more first supporting structures 305 are formed on semiconductor layer 301 and extend in staircase region 311 and core region 313 of stack structure 303 in the z-direction. First supporting structures 305 may be provided by forming one or more through holes by an etching process (e.g., wet etching, dry etching, or a combination thereof) through stack structure 303, and then filling (e.g., depositing) the through holes by dielectric materials. In some implementations, first supporting structures 305 may be formed before forming stack structure 303. Next, a hard mask 321 is formed on stack structure 303. In some implementations, hard mask 321 includes dielectric materials including, but not limited to, silicon oxide, silicon nitride, silicon oxynitride, aluminum oxide, or any combination thereof. For instance, hard mask 321 may include aluminum oxide.

FIG. 6B shows a cross-sectional view of FIG. 5C along C-C plane. As shown in FIGS. 6B-6C, different from implementations in FIGS. 5A-5O, second hard mask through holes 321-3 are formed before forming first hard mask through holes 321-1. As such, hard mask 321 is formed on stack structure 303, and then stack structure 303 is etched through hard mask 321 to form second hard mask through holes 321-3.

Next, similar to FIGS. 5B-5H, FIGS. 6D-6J show the fabrication process of first hard mask through holes 321-1 after forming second hard mask through holes 321-3.

FIG. 6D is a cross-sectional view of FIG. 6E along D-D plane. As shown in FIGS. 6B and 6E, hard mask 321 is partially removed to form one or more first hard mask through holes 321-1. First hard mask through holes 321-1 may extend in the y-direction and may be arranged side-by-side in the x-direction. Each first hard mask through holes 321-1 represents a location of a corresponding step of steps in staircase region 311 to be etched. It is noted that the location of first hard mask through holes 321-1 may not be overlapped with that of first supporting structures 305.

Next, as shown in FIG. 6F, a photoresist layer 323 is partially formed on hard mask 321 to expose a first set of first hard mask through holes 321-1. Next, etch a first time through photoresist layer 323 via the first set of first hard mask through holes 321-1 to remove a first pair of dielectric layer 303-3 and sacrificial layer 303-5. The etching process may be done by using wet etching, dry etching, or a combination thereof. In some implementations, the etching process to remove a pair of dielectric layer 303-3 and sacrificial layer 303-5 can be done by using an “end-point” feature of etching equipment as mentioned above.

Next, as shown in FIG. 6G, after through holes penetrating the first pair of dielectric layer 303-3 and sacrificial layer 303-5 are formed, photoresist layer 323 is further partially removed (e.g., trimmed) to expose a second set of hard mask through holes 321-1. Next, etch a second time through photoresist layer 323 via the first set of first hard mask through holes 321-1 to remove a second pair of dielectric layer 303-3 and sacrificial layer 303-5, and via the second set of first hard mask through holes 321-1 to remove a first pair of dielectric layer 303-3 and sacrificial layer 303-5, where the second pair of dielectric layer 303-3 and sacrificial layer 303-5 are one pair below the first pair of dielectric layer 303-3 and sacrificial layer 303-5. By repeating the process, as shown in FIGS. 6H-6J, each pair of dielectric layer 303-3 and sacrificial layer 303-5 has a respective first hard mask through hole 321-1 extending therein.

Next, after forming the hard mask through holes, as shown in FIG. 6K, etch stop materials are filled in the hard mask through holes to form one or more etch stop structures 307. Each etch stop structure 307 extends into stack structure 303 and is in contact with one of dielectric layers 353-3.

Next, as shown in FIG. 6L, sacrificial layers (e.g., 303-5 in FIG. 6K) are partially removed until etch stop structures 307. The removal of the sacrificial layers may be wet etching, dry etching, or a combination thereof. In this implementation, the removal of the sacrificial layers is wet etching by using etching solvent that can selectively remove sacrificial layers without removing or at least hardly removing dielectric layers 303-3 and/or first supporting structures 305. In some implementations, a material of sacrificial layer 303-5 and that of etch stop structure 307 have a high etching selectivity of equal or more than 5. After the removal of the sacrificial layers, vacancies 303-7 are left unfilled. As such, during this stage, first supporting structures 305 can provide sufficient support for stack structure 303 and prevent stack structure 303 from collapsing or cracking down.

Next, as shown in FIG. 6M, these vacancies are then filled with conductive materials to form conductive layers 303-1. In some implementations, a conductive material to form conductive layer 303-1 includes W, Co, Cu, Al, polysilicon, doped silicon, silicides, or any combination thereof. The deposition process of the conductive materials includes atomic-layer deposition (ALD), chemical vapor deposition (CVD), physical vapor deposition (PVD), or a combination thereof.

Next, as shown in FIG. 6N, after replacing the sacrificial layers with conductive layers, the conductive layers extend in stack structure 303 in a lateral direction to etch stop structures 307. Since each conductive layer is formed stepwise due to the forming of etch stop structures 307, contact structures 309 may be formed on and in contact with corresponding conductive layers. To form contact structures 309, another etching process may be provided to form through holes extending into stack structure 303 to the corresponding conductive layers. And then, conductive materials can be filled into these through holes to form these contact structures 309.

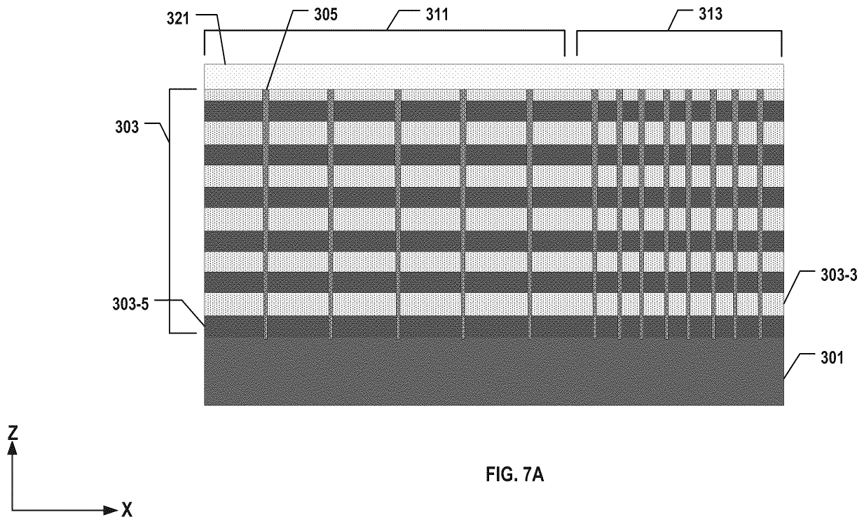

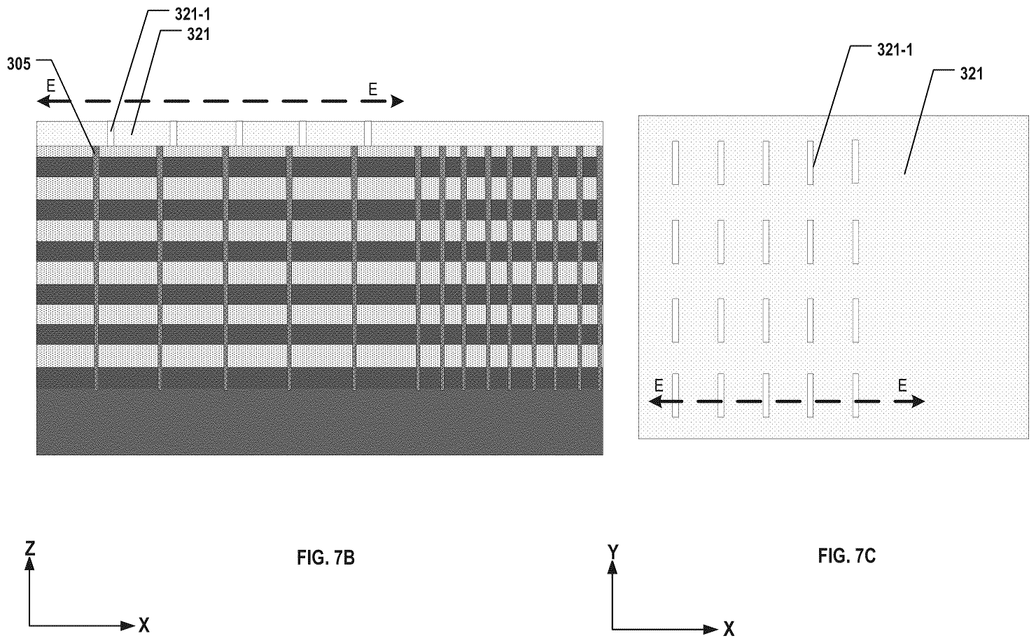

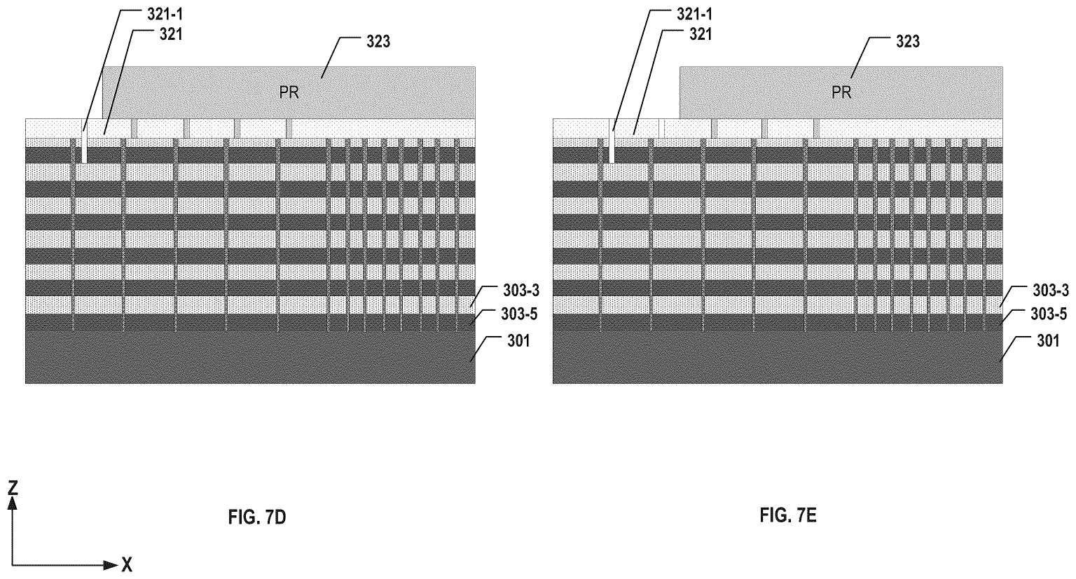

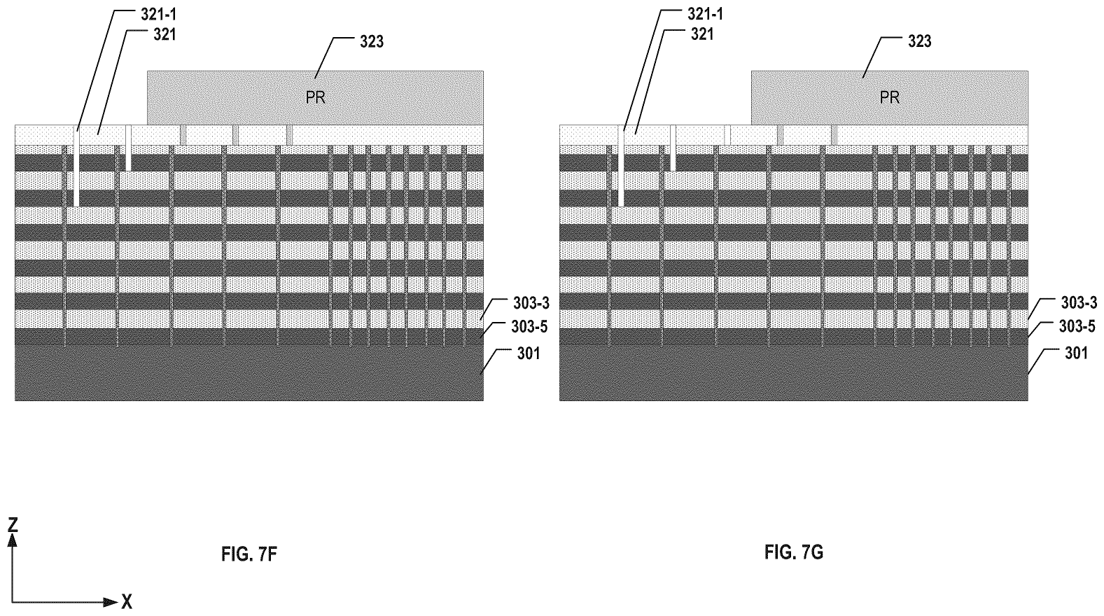

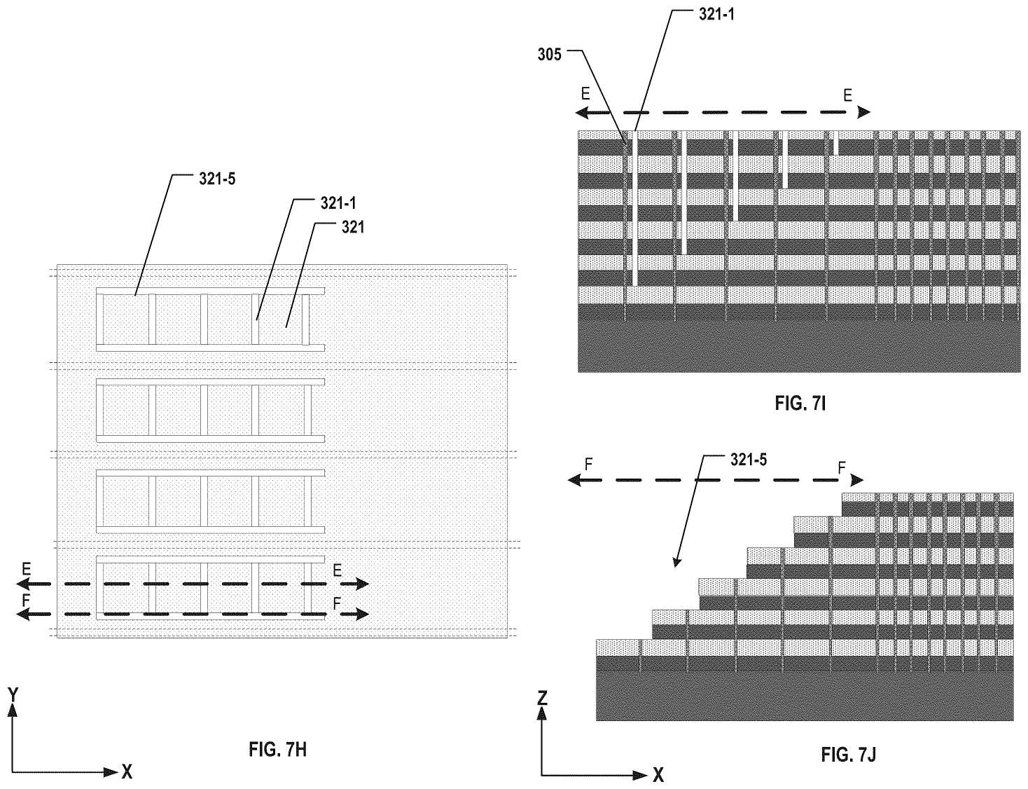

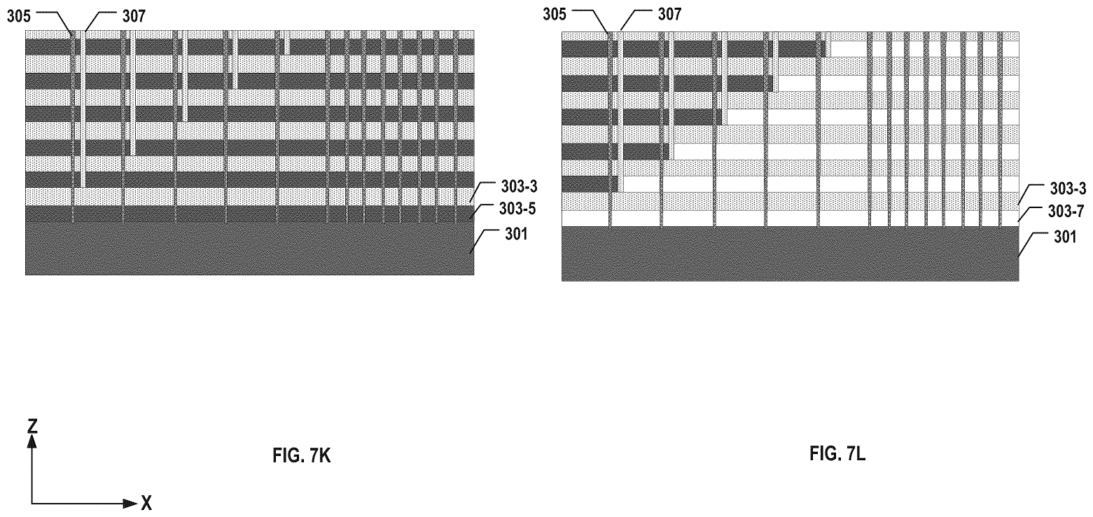

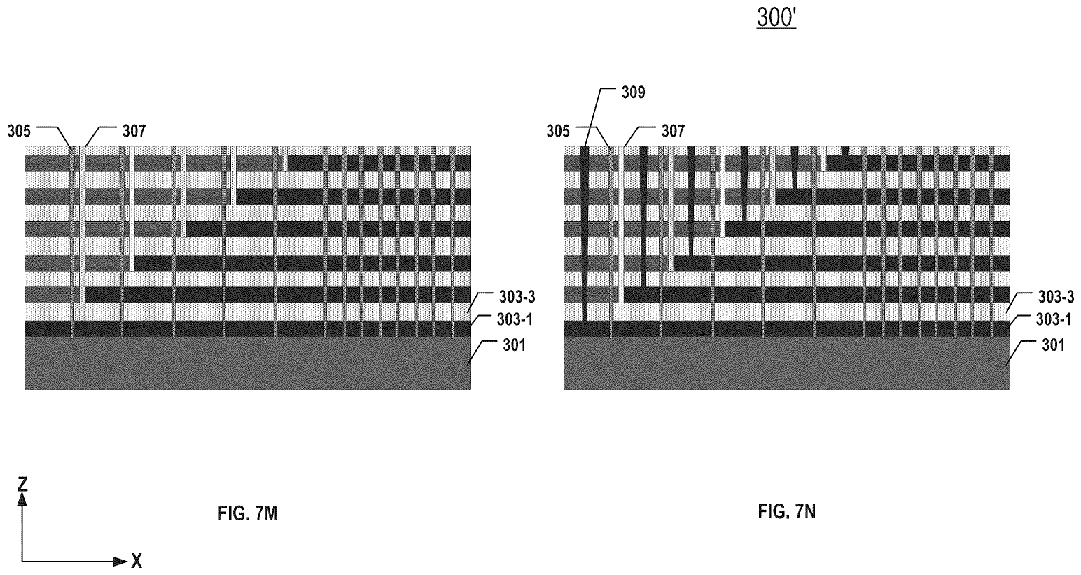

FIGS. 7A-7N provide a process flow of forming 3D memory device 300′ which is similar to implementations in FIGS. 5A-5O. For ease of description, the same or similar processes to FIGS. 5A-5O will be omitted.

As shown in FIG. 7A, semiconductor layer 301 is provided, and stack structure 303 including interleaved dielectric layers 303-3 and sacrificial layers 303-5 are formed on semiconductor layer 301. After forming stack structure 303, one or more first supporting structures 305 are formed on semiconductor layer 301 and extend in staircase region 311 and core region 313 of stack structure 303 in the z-direction. First supporting structures 305 may be provided by forming one or more through holes by an etching process (e.g., wet etching, dry etching, or a combination thereof) through stack structure 303, and then filling (e.g., depositing) the through holes by dielectric materials. In some implementations, first supporting structures 305 may be formed before forming stack structure 303. Next, a hard mask 321 is formed on stack structure 303. In some implementations, hard mask 321 includes dielectric materials including, but not limited to, silicon oxide, silicon nitride, silicon oxynitride, aluminum oxide, or any combination thereof. For instance, hard mask 321 may include aluminum oxide.

Next, FIG. 7B shows a cross-sectional view of FIG. 7C along E-E plane. As shown in FIGS. 7B-7C, similar to implementations in FIGS. 5B-5C, first hard mask through holes 321-1 are formed before forming second hard mask through holes 321-5. However, it is noted that the order for forming first hard mask through holes 321-1 and second hard mask through holes 321-5 may be switched according to some implementations. As such, hard mask 321 is formed on stack structure 303, and then stack structure 303 are etched through hard mask 321 to form second hard mask through holes 321-5.

Next, similar to FIGS. 5D-5G, FIGS. 7D-7G show the fabrication process of first hard mask through holes 321-1 after forming second hard mask through holes 321-5.

Next, as shown in FIG. 7D, a photoresist layer 323 is partially formed on hard mask 321 to expose a first set of first hard mask through holes 321-1. Next, etch a first time through photoresist layer 323 via the first set of first hard mask through holes 321-1 to remove a first pair of dielectric layer 303-3 and sacrificial layer 303-5. The etching process may be done by using wet etching, dry etching, or a combination thereof. In some implementations, the etching process to remove a pair of dielectric layer 303-3 and sacrificial layer 303-5 can be done by using an “end-point” feature of etching equipment as mentioned above.

Next, as shown in FIG. 7E, after through holes penetrating the first pair of dielectric layer 303-3 and sacrificial layer 303-5 are formed, photoresist layer 323 is further partially removed (e.g., trimmed) to expose a second set of first hard mask through holes 321-1. Next, etch a second time through photoresist layer 323 via the first set of first hard mask through holes 321-1 to remove a second pair of dielectric layer 303-3 and sacrificial layer 303-5, and via the second set of first hard mask through holes 321-1 to remove a first pair of dielectric layer 303-3 and sacrificial layer 303-5, where the second pair of dielectric layer 303-3 and sacrificial layer 303-5 are one pair below the first pair of dielectric layer 303-3 and sacrificial layer 303-5. By repeating the process, as shown in FIGS. 7F-7G, each pair of dielectric layer 303-3 and sacrificial layer 303-5 has a respective first hard mask through hole 321-1 extending therein.

FIG. 7J shows a cross-sectional view of FIG. 7H along F-F plane, and FIG. 7I shows a cross-sectional view of FIG. 7H along E-E plane. Next, as shown in FIGS. 7H-7J, one or more second hard mask through holes 321-5 are formed extending through stack structure 303 in the z-direction and also along the x-direction. Unlike the implementations in FIG. 5K, as FIG. 7J shown, second hard mask through holes 321-5 of the present implementations may not extend to semiconductor layer 301 or the pair of dielectric layer and sacrificial layer adjacent to semiconductor layer 301, but extend stepwise as to the corresponding steps of first hard mask through holes 321-1 as in FIG. 7I. The etching of second hard mask through holes 321-5 may be done by using wet etching, dry etching, or a combination thereof. In some implementations, the stepwise second hard mask through holes 321-5 may be formed by using multiple etching (e.g., trimming) process.

Next, after forming the hard mask through holes, as shown in FIG. 7K, etch stop materials are filled in the hard mask through holes to form one or more etch stop structures 307. Each etch stop structure 307 extends into stack structure 303 and is in contact with one of dielectric layers 353-3. The stepwise second hard mask through holes 321-5 and etch stop structures 307 formed in the stepwise second hard mask through holes 321-5 may provide a better stress adjustment for stack structure 303.

Next, as shown in FIG. 7L, sacrificial layers (e.g., 303-5 in FIG. 7K) are partially removed until etch stop structures 307. The removal of the sacrificial layers may be wet etching, dry etching, or a combination thereof. In this implementation, the removal of the sacrificial layers is wet etching by using etching solvent that can selectively remove sacrificial layers without removing or at least hardly removing dielectric layers 303-3 and/or first supporting structures 305. In some implementations, a material of sacrificial layer 303-5 and that of etch stop structure 307 have a high etching selectivity of equal or more than 5. After the removal of the sacrificial layers, vacancies 303-7 are left unfilled. As such, during this stage, first supporting structures 305 can provide sufficient support for stack structure 303 and prevent stack structure 303 from collapsing or cracking down.

Next, as shown in FIG. 7M, these vacancies are then filled with conductive materials to form conductive layers 303-1. In some implementations, a conductive material to form conductive layer 303-1 includes W, Co, Cu, Al, polysilicon, doped silicon, silicides, or any combination thereof. The deposition process of the conductive materials includes atomic-layer deposition (ALD), chemical vapor deposition (CVD), physical vapor deposition (PVD), or a combination thereof.

As shown in FIG. 7N, after replacing the sacrificial layers with conductive layers, the conductive layers extend in stack structure 303 in a lateral direction to etch stop structures 307. Since each conductive layer is formed stepwise due to the forming of etch stop structures 307, contact structures 309 may be formed on and in contact with corresponding conductive layers. To form contact structures 309, another etching process may be provided to form through holes extending into stack structure 303 to the corresponding conductive layers. And then, conductive materials can be filled into these through holes to form these contact structures 309. As such, 3D memory device 300′ is formed thereafter.

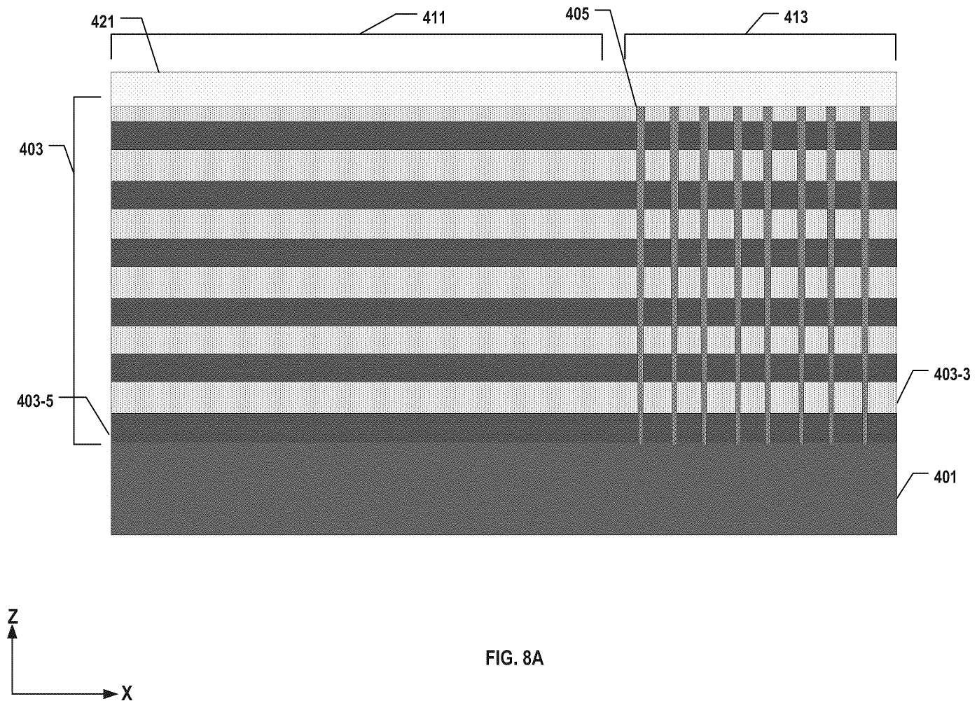

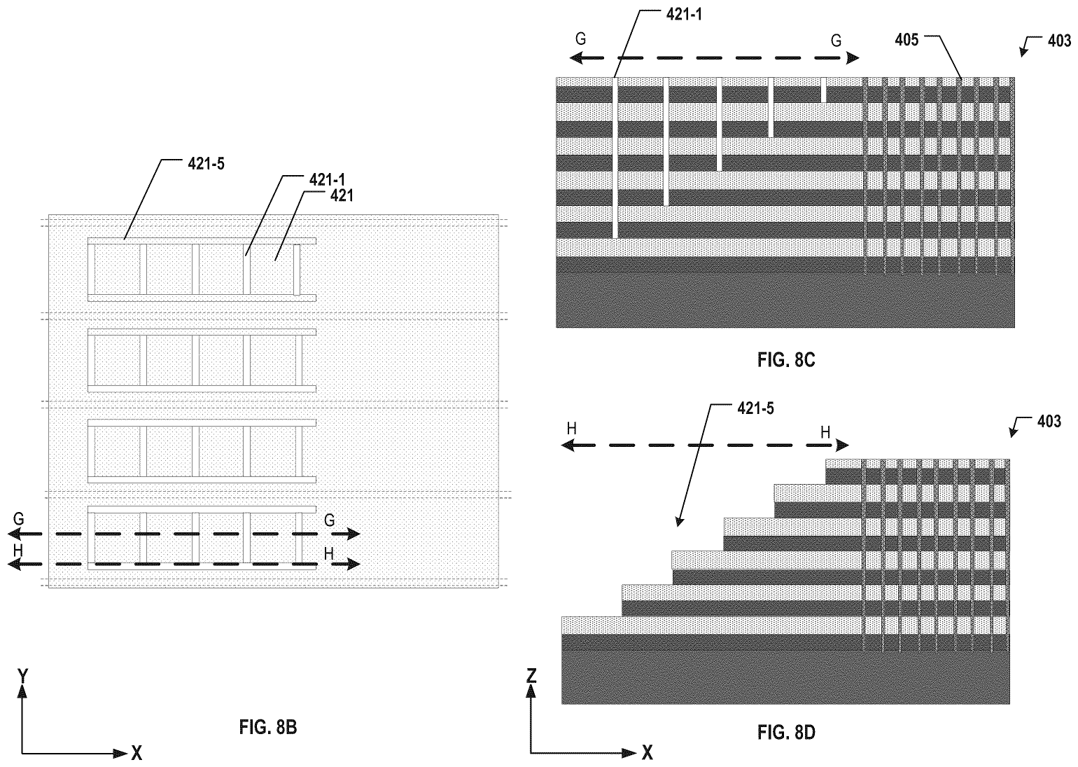

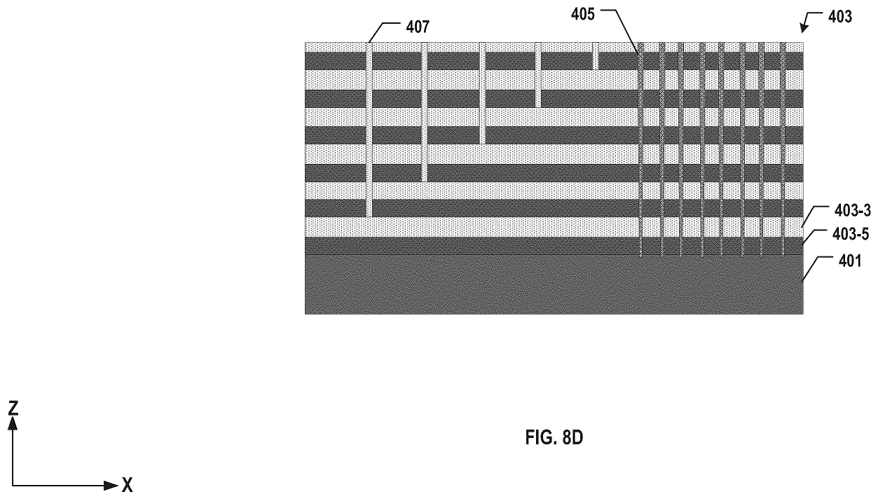

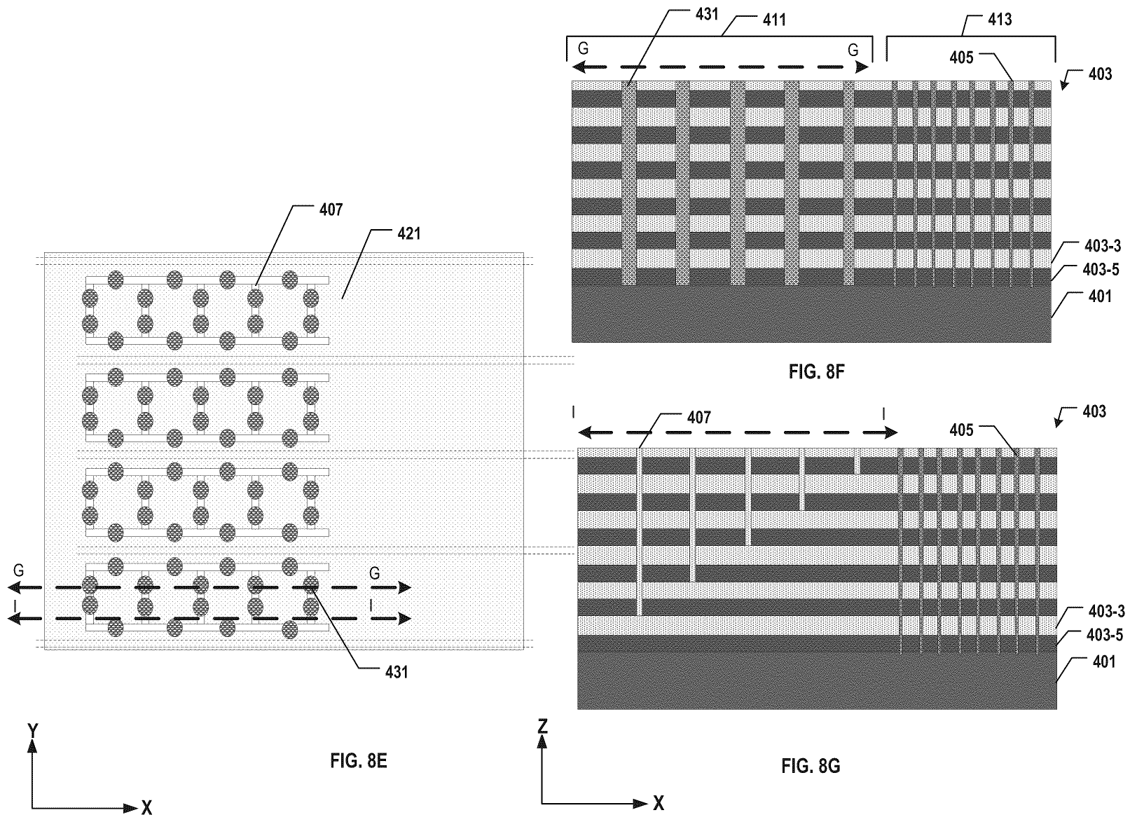

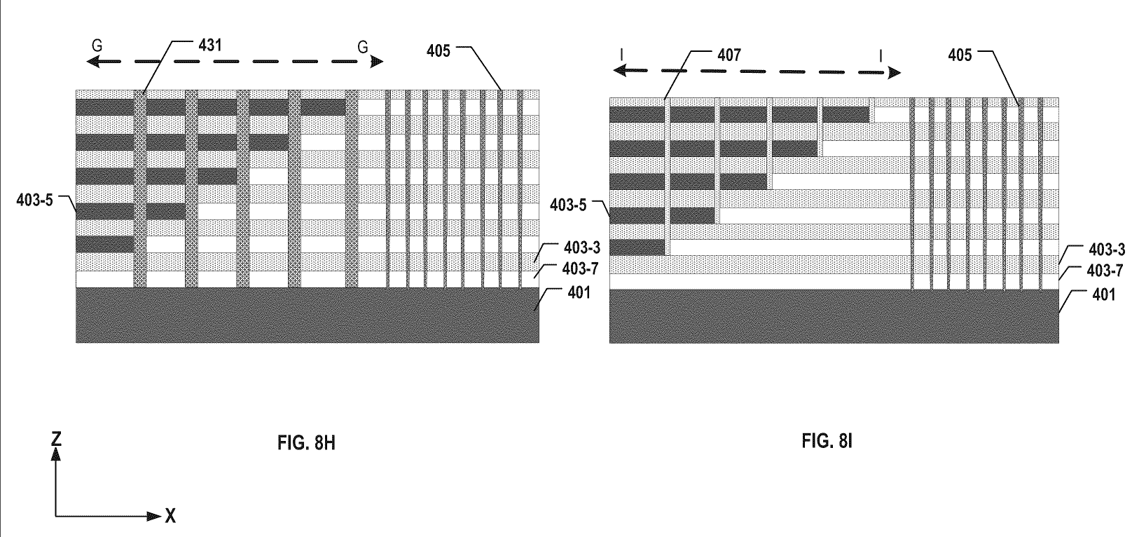

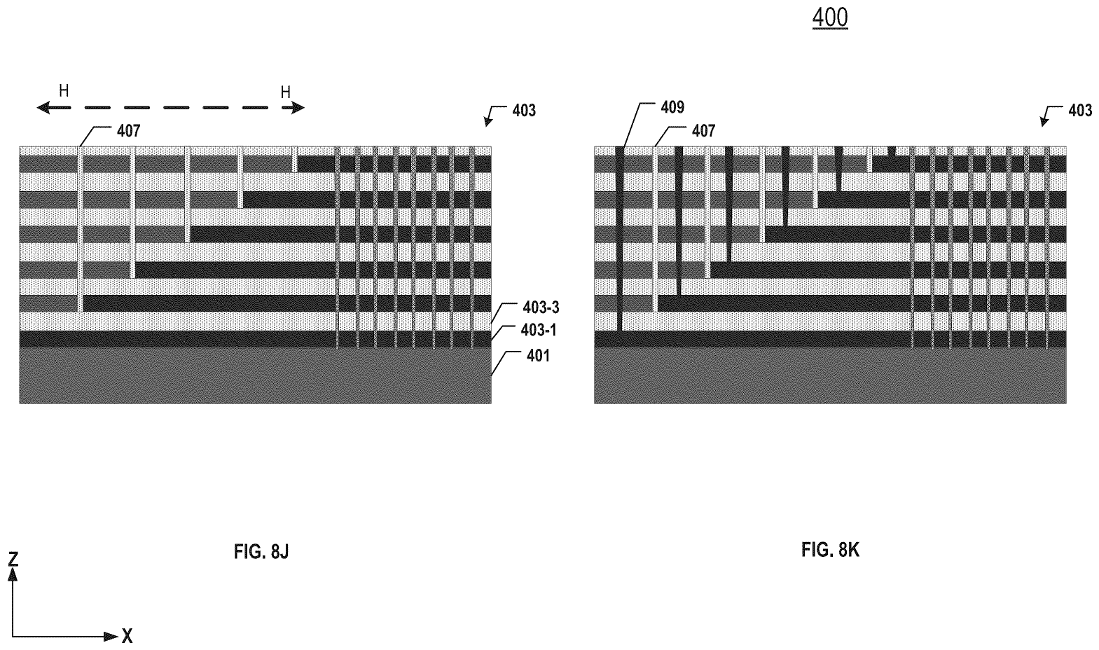

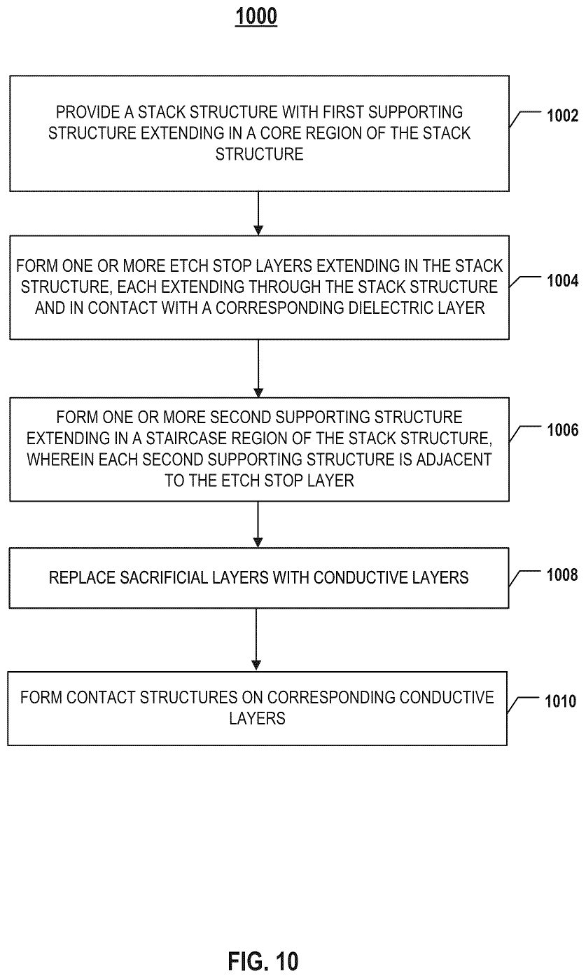

FIGS. 8A-8K illustrate a fabrication process for forming an exemplary 3D memory device 400, according to various embodiments of the present disclosure. FIG. 10 is a flowchart of a method 1000 for forming the exemplary 3D memory device 400. It is understood that the operations shown in method 1000 are not exhaustive and that other operations can be performed as well before, after, or between any of the illustrated operations. Further, some of the operations may be performed simultaneously, or in a different order than shown in FIGS. 8A-8K.

Referring to FIG. 10, method 1000 starts at operation 1002, in which a stack structure with one or more first supporting structure extending in a core regions of the stack structure is formed. FIG. 8A illustrates a corresponding structure.

As shown in FIG. 8A, semiconductor layer 401 is provided, and stack structure 403 including interleaved dielectric layers 403-3 and sacrificial layers 403-5 are formed on semiconductor layer 401. After forming stack structure 403, one or more first supporting structures 405 are formed on semiconductor layer 401 and extend in core region 413 of stack structure 403 in the z-direction. First supporting structures 405 may be provided by forming one or more through holes by an etching process (e.g., wet etching, dry etching, or a combination thereof) through stack structure 403, and then filling (e.g., depositing) the through holes by dielectric materials. In some implementations, first supporting structures 405 may be formed before forming stack structure 403. Next, a hard mask 421 is formed on stack structure 403. In some implementations, hard mask 421 includes dielectric materials including, but not limited to, silicon oxide, silicon nitride, silicon oxynitride, aluminum oxide, or any combination thereof. For instance, hard mask 421 may include aluminum oxide.

Referring to FIG. 10, method 1000 proceeds to operation 1004, in which one or more etch stop structures extending in the stack structure are provided. Each etch stop structure extends through the stack structure and is in contact with a corresponding dielectric layer. FIGS. 8B-8D illustrate corresponding structures.

FIG. 8C is a cross-sectional view of FIG. 8B along G-G plane, and FIG. 8D is a cross-sectional view of FIG. 8B along H-H plane. As shown in FIGS. 8B and 8C, one or more first hard mask through holes 421-1 are formed extending through stack structure 403 in the z-direction and also along the x-direction. For ease of description, the stepwise first hard mask through holes 421-1 may be formed by using the same process or similar to FIGS. 7B-7J. Also, as shown in FIGS. 8B and 8D, one or more second hard mask through holes 421-5 are formed extending through stack structure 403 in the z-direction and also along the x-direction. In some implementations, as shown in FIG. 8B, each second hard mask through hole 421-5 extends in a direction perpendicular to that of first hard mask through hole 421-1. Second hard mask through holes 421-5 may extend to semiconductor layer 401 or to a pair of dielectric layer and sacrificial layer adjacent to semiconductor layer 401. The etching of second hard mask through holes 421-5 may be done by using wet etching, dry etching, or a combination thereof. It is noted that first hard mask through holes 421-1 may be formed before or after forming second hard mask through holes 421-5.

Next, after forming the hard mask through holes, as shown in FIG. 8D, etch stop materials are filled in the hard mask through holes to form one or more etch stop structures 407. Each etch stop structure 407 extends into stack structure 403 and is in contact with one of dielectric layers 453-3.

Referring to FIG. 10, method 1000 proceeds to operation 1006, in which one or more second supporting structures are formed and extend in a staircase region of the stack structure. Each second supporting structure is adjacent to one of the etch stop structures. FIGS. 8E-8G illustrate corresponding structures.

FIG. 8F is a cross-sectional view of FIG. 8E along G-G plane, and FIG. 8G is a cross-sectional view of FIG. 8E along I-I plane. As shown in FIGS. 8E and 8F, one or more second supporting structures 431 are formed and extend in staircase region 411 of stack structure 403. Each second supporting structure 431 is adjacent to (e.g., in contact with) etch stop structures 407 in a lateral direction (e.g., x- or y-direction). In some implementations, each second supporting structure 431 extends to semiconductor layer 401. In some implementations, each of second supporting structures 431 is formed between etch stop structures 407. In some implementations, each second supporting structure 431 has a round shape in a top view and has a diameter more than that of etch stop structure 407. In some implementations, the diameter of second supporting structures 431 is larger than the width of etch stop structures 407. In some implementations, the diameter of second supporting structures 431 may be ranged from 50 nm to 300 nm, e.g., 50 nm, 60 nm, 70 nm, 80 nm, 90 nm, 100 nm, 150 nm, 200 nm, 250 nm, 300 nm, etc. In some implementations, second supporting structures 431 are distributed side-by-side along the x-direction and/or y-direction of etch stop structures 407.

To form second supporting structures 431, an etching process may be applied to stack structure 403 to form one or more second supporting structures through holes (not shown) distributed side-by-side along the x-direction and/or y-direction of etch stop structures 407 and at least partially overlapped by or covering etch stop structures 407. That is, these second supporting structures through holes may cut off etch stop structures 407 to become discontinuous etch stop structures 407. The diameter of these second supporting structures through holes may be larger than the width of etch stop structures 407. In some implementations, these second supporting structures through holes may extend to semiconductor layer 401. Next, the second supporting structures are filled with dielectric materials to form second supporting structures 431.

Referring to FIG. 10, method 1000 proceeds to operation 1008, in which sacrificial layers are replaced with conductive layers. FIGS. 8H-8J illustrate corresponding structures.

As shown in FIGS. 8H and 8I, sacrificial layers 403-5 are partially removed until etch stop structures 407 or second supporting structures 431 between two discontinuous etch stop structures 407. The removal of the sacrificial layers may be wet etching, dry etching, or a combination thereof. In this implementation, the removal of the sacrificial layers is wet etching by using etching solvent that can selectively remove sacrificial layers without removing or at least hardly removing dielectric layers 403-3 and/or first supporting structures 405, and/or second supporting structures 431. In some implementations, a material of sacrificial layer 403-5 and that of etch stop structure 407 have a high etching selectivity of equal or more than 5. After the removal of the sacrificial layers, vacancies 403-7 are left unfilled. As such, during this stage, first supporting structures 405 can provide sufficient support for stack structure 403 in the core region, and second supporting structures 431 can provide sufficient support for stack structure 403 in the staircase region to prevent stack structure 403 from collapsing or cracking down. Second supporting structures 431 that formed between the discontinuous etch stop structures 407 may further decrease area consumption for additional supporting structures in the staircase region, thereby increasing the overall performance of the 3D memory device as well as providing more process windows for forming the etch stop structures.

Next, as shown in FIG. 8J, these vacancies are then filled with conductive materials to form conductive layers 403-1. In some implementations, a conductive material to form conductive layer 403-1 includes W, Co, Cu, Al, polysilicon, doped silicon, silicides, or any combination thereof. The deposition process of the conductive materials includes atomic-layer deposition (ALD), chemical vapor deposition (CVD), physical vapor deposition (PVD), or a combination thereof.

Referring to FIG. 10, method 1000 proceeds to operation 1010, in which contact structures are formed on corresponding conductive layers. FIG. 8K illustrates corresponding structures.

As shown in FIG. 8K, after replacing the sacrificial layers with conductive layers, the conductive layers extend in stack structure 403 in a lateral direction until etch stop structures 407 or second supporting structures 431 between two discontinuous etch stop structures 407. Since each conductive layer is formed stepwise due to the forming of etch stop structures 407, contact structures 409 may be formed on and in contact with corresponding conductive layers. To form contact structures 409, another etching process may be provided to form through holes extending into stack structure 403 to the corresponding conductive layers. And then, conductive materials can be filled into these through holes to form these contact structures 409. 3D memory device 400 is formed thereafter.

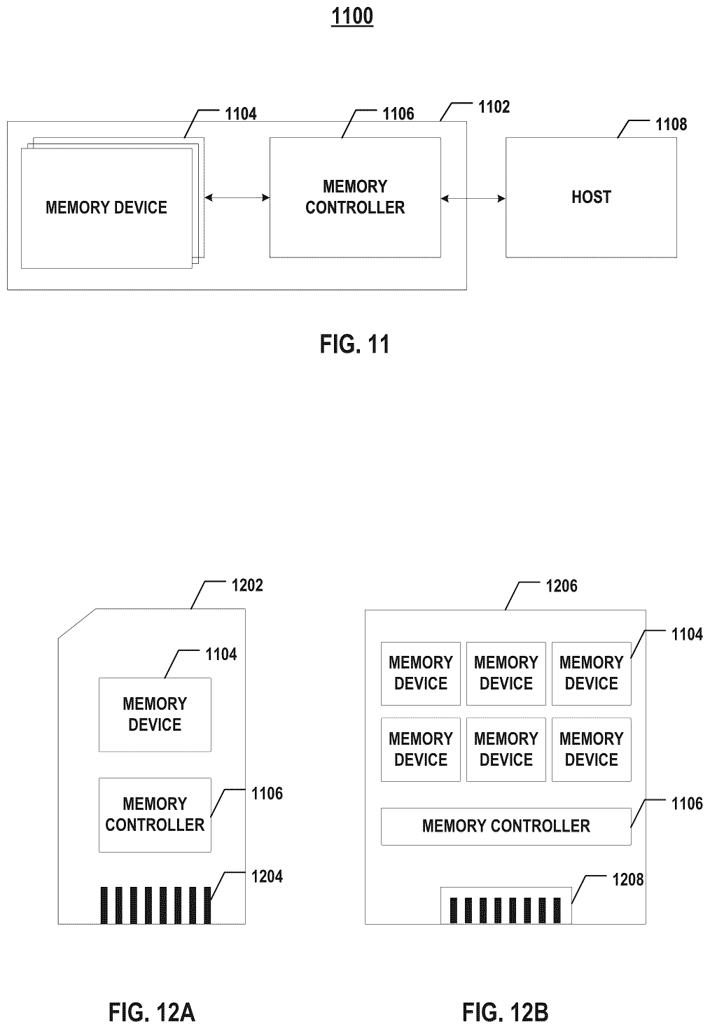

FIG. 11 illustrates a block diagram of a system 1100 having a memory device, according to some aspects of the present disclosure. System 1100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 11, system 1100 can include a host 1108 and a memory system 1102 having one or more memory devices 1104 and a memory controller 1106. Host 1108 can be a processor of an electronic device, such as a central processing unit (CPU), or a system-on-chip (SoC), such as an application processor (AP). Host 1108 can be configured to send or receive the data to or from memory devices 1104.

Memory devices 1104 can be any memory devices disclosed herein, such as 3D memory devices 100, 300, 300′, or 400. In some implementations, each memory device 1104 includes a 3D memory device, as described above in detail.

Memory controller 1106 is coupled to memory device 1104 and host 1108 and is configured to control memory device 1104, according to some implementations. Memory controller 1106 can manage the data stored in memory device 1104 and communicate with host 1108. In some implementations, memory controller 1106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1106 can be configured to control operations of memory device 1104, such as read, erase, and program operations. Memory controller 1106 can also be configured to manage various functions with respect to the data stored or to be stored in memory device 1104 including, but not limited to bad-block management, garbage collection, logical-to-physical address conversion, wear leveling, etc. In some implementations, memory controller 1106 is further configured to process error correction codes (ECCs) with respect to the data read from or written to memory device 1104. Any other suitable functions may be performed by memory controller 1106 as well, for example, formatting memory device 1104. Memory controller 1106 can communicate with an external device (e.g., host 1108) according to a particular communication protocol. For example, memory controller 1106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1106 and one or more memory devices 1104 can be integrated into various types of storage devices, for example, be included in the same package, such as a universal Flash storage (UFS) package or an eMMC package. That is, memory system 1102 can be implemented and packaged into different types of end electronic products. In one example as shown in FIG. 12A, memory controller 1106 and a single memory device 1104 may be integrated into a memory card 1202. Memory card 1202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1202 can further include a memory card connector 1204 coupling memory card 1202 with a host (e.g., host 1108 in FIG. 11). In another example as shown in FIG. 12B, memory controller 1106 and multiple memory devices 1104 may be integrated into an SSD 1206. SSD 1206 can further include an SSD connector 1208 coupling SSD 1206 with a host (e.g., host 1108 in FIG. 11). In some implementations, the storage capacity and/or the operation speed of SSD 1206 is greater than those of memory card 1202.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A three-dimensional (3D) memory device, comprising:
a semiconductor layer;
a stack structure on the semiconductor layer, wherein the stack structure comprises alternating conductive layers and first dielectric layers and has a core region and a staircase region adjacent to the core region;
one or more stop structures in contact with the corresponding conductive layers and extending through the staircase region of the stack structure in a first direction toward the semiconductor layer; and
second dielectric layers, each between two of the first dielectric layers, wherein each of the one or more stop structures is between one of the second dielectric layers and one of the conductive layers.

2. The 3D memory device of claim 1, wherein a material of the second dielectric layers is different from that of the stop structures, and a material of the second dielectric layers and that of the stop structures have an etching selectivity of equal or more than 5.

3. The 3D memory device of claim 1, wherein one or more first stop structures of the stop structures extends in a second direction perpendicular to the first direction and one or more second stop structure of the stop structures extends in a third direction perpendicular to the first direction and the second direction, wherein one of the first stop structures connects between two of the second stop structures.

4. The 3D memory device of claim 1, further comprising:
one or more first supporting structures in contact with the semiconductor layer and extending through the core region of the stack structure; and
one or more second supporting structures in contact with the semiconductor layer and extending through the staircase region of the stack structure.

5. The 3D memory device of claim 4, wherein a diameter of each of the second supporting structures is larger than a width of each of the stop structures, and the diameter of each of the second supporting structures is ranged from 50 nm to 300 nm.

6. The 3D memory device of claim 4, wherein the second supporting structures are arranged side-by-side along a second direction in which stop structures extending, wherein the second direction is perpendicular to the first direction.

7. The 3D memory device of claim 4, wherein each of the second supporting structures is in contact with one of the stop structures.

8. The 3D memory device of claim 4, wherein each of the second supporting structures is not in contact with one of the stop structures.

9. The 3D memory device of claim 8, wherein one or more first stop structures of the stop structures extends in a second direction perpendicular to the first direction, and one or more second stop structure of the stop structures extends in a third direction perpendicular to the first direction and the second direction,
wherein one of the first stop structures connects between two of the second stop structures, and
wherein one of the second stop structures extends in the first direction and is in contact with one of the first dielectric layer.

10. The 3D memory device of claim 9, wherein one of the second stop structures has a rectangular cross-section.

11. The 3D memory device of claim 9, wherein one or more first stop structures of the stop structures extends in a second direction perpendicular to the first direction, and one or more second stop structure of the stop structures extends in a third direction perpendicular to the first direction and the second direction,
wherein one of the first stop structures connects between two of the second stop structures, and
wherein one of the second stop structures has a stepwise cross-section.

12. A system, comprising:
a three-dimensional (3D) memory device configured to store data, the 3D memory device comprising:
a semiconductor layer;
a stack structure on the semiconductor layer, wherein the stack structure comprises alternating conductive layers and first dielectric layers and has a core region and a staircase region adjacent to the core region;
one or more stop structures in contact with the corresponding conductive layers and extending through the staircase region of the stack structure in a first direction toward the semiconductor layer; and
second dielectric layers, each between two of the first dielectric layers, wherein each of the one or more stop structures is between one of the second dielectric layers and one of the conductive layers; and
a memory controller coupled to the 3D memory device and configured to control the 3D memory device.

13. A method for a three-dimensional (3D) memory device, comprising:
forming a stack structure on a semiconductor layer, wherein the stack structure comprises alternating sacrificial layers and dielectric layers and has a core region and a staircase region adjacent to the core region;
forming one or more stop structures in contact with the corresponding dielectric layers and extending through the staircase region of the stack structure in a first direction toward the semiconductor layer; and
replacing a part of the sacrificial layers with conductive layers, wherein each of the one or more stop structures is between one of the sacrificial layers and one of the conductive layers.

14. The method of claim 13, further comprising:
forming one or more contact structures in contact with the corresponding conductive layers.

15. The method of claim 13, wherein replacing a part of the sacrificial layers with conductive layers comprises:
etching to remove the part of the sacrificial layers until the one or more stop structures; and
filling vacancies after removing the part of the sacrificial layers with conductive materials.

16. The method of claim 13, further comprising:
forming one or more first supporting structures in contact with the semiconductor layer and extending through the core region of the stack structure in the first direction toward the semiconductor layer; and
forming one or more second supporting structures in contact with the semiconductor layer and extending through the staircase region of the stack structure, wherein each of the second supporting structures is in contact with one of the stop structures.

17. The method of claim 13, wherein forming one or more second supporting structures in contact with the semiconductor layer and extending through the staircase region of the stack structure further comprises:
etching of the stack structure to form one or more second supporting structure through holes overlapping at least a part of the one or more stop structures; and
filling the one or more second supporting structure through holes with dielectric materials to form the one or more second supporting structures.

18. The method of claim 13, wherein forming one or more first supporting structures in contact with the semiconductor layer and extending through the core region of the stack structure in the first direction toward the semiconductor layer further comprises:
etching of the stack structure to form one or more first supporting structure through holes in the core region of the stack structure extending to the semiconductor layer in the first direction; and
filling the one or more first supporting structure through holes with dielectric materials to form the one or more first supporting structures.

19. The method of claim 13, wherein forming one or more stop structures in contact with the corresponding dielectric layers and extending through the staircase region of the stack structure in the first direction further comprises:
forming a hard mask on the stack structure with a pattern;
etching through a first pair of the sacrificial layers and dielectric layers of the stack structure via a first part of the pattern of the hard mask by covering up the rest part of the pattern with a photoresist layer on the hard mask;
trimming the photoresist layer to uncover a second part of the pattern of the hard mask; and
etching through a second pair of the sacrificial layers and dielectric layers of the stack structure via the first part of the pattern of the hard mask, and etching through the first pair of the sacrificial layers and dielectric layers of the stack structure via the second part of the pattern of the hard mask.

20. The method of claim 19, wherein etching through a first pair of the sacrificial layers and dielectric layers of the stack structure comprises:
etching through the stack structure until a pre-determined condition is met, wherein the pre-determined condition comprises detecting a pre-determined element of etching residues.
